(19) United States
(12) Patent Application Publication
(10) Pub. No.: US 2025/0293025 A1
(43) Pub. Date: Sep. 18, 2025

(54) METHOD FOR MANUFACTURING GROUP III NITRIDE SEMICONDUCTOR TEMPLATE AND SEMICONDUCTOR TEMPLATE MANUFACTURED THEREBY

(71) Applicant: WAVELORD CO., LTD, Hwaseong-si (KR)

(72) Inventors: Juneo SONG, Suwon-si (KR); Hyeong Seon YUN, Paju-si (KR); Young Hun HAN, Osan-si (KR); Ji Hyung MOON, Gunpo-si (KR)

(73) Assignee: WAVELORD CO., LTD, Hwaseong-si (KR)

(21) Appl. No.: 18/860,626

(22) PCT Filed: Aug. 23, 2023
(86) PCT No.: PCT/KR2023/012452

§ 371 Date: Oct. 26, 2024

(30) Foreign Application Priority Data
Aug. 23, 2022 (KR) 10-2022-0105326
Sep. 14, 2022 (KR) 10-2022-0115558

(51) Int. Cl. H01L 21/02; C30B 25/18; C30B 29/40; C30B 33/04; C30B 33/12; H01L 21/3065

(52) U.S. Cl. CPC H01L 21/0254; C30B 25/18; C30B 29/403; C30B 33/04; C30B 33/12; H01L 21/3065

(57) ABSTRACT

The present invention relates to: a method for manufacturing a group III nitride semiconductor template, by which a high-quality group III nitride semiconductor layer can be formed on the top of a high heat dissipation support substrate having a lattice constant and thermal expansion coefficient equal or similar to those of the group III nitride semiconductor layer, by using a laser lift off (LLO) technique; and a semiconductor template manufactured thereby.

### TECHNICAL FIELD

The present invention relates to a method of manufacturing a group III nitride semiconductor template and a semiconductor template manufactured using the same.

### BACKGROUND ART

Conventional group III nitride semiconductor thin film materials and power semiconductor device structures using the same are grown and formed on a Si single crystalline wafer for a growth substrate, and in this case, the structure is formed by sequentially stacking a Si re-melting prevention film region including AlN materials (nitride or nitride oxide including an Al composition) that suppresses re-melting through reaction with a surface layer of the Si single crystalline wafer, a transition region including AlGaN materials (group III nitride including an Al or Ga composition) for tensile stress relief, and a power semiconductor active region including GaN materials (group III nitride including a Ga composition). Here, as a crystal face of the Si single crystalline wafer, a (111) face in which Si atomic bonds are most dense may be used, but a (110) or (100) face may be used according to applied products.

Typically, a metal organic chemical vapor deposition (MOCVD) device is used for the growth and formation of a GaN material-based single crystalline thin film and a power semiconductor device structure on a Si single crystalline wafer for a group III nitride power semiconductor growth substrate, and in this case, the GaN material-based single crystalline thin film growth (deposition) process containing gallium (Ga) atoms is basically performed at a high temperature of about 1000° C. and in a reducing atmosphere (H₂, H⁺, NH₃, radical ions), and the Si re-melting prevention film region is absolutely required to block Si—Ga metallic eutectic reactions actively occurring with relatively small energy between the surface layer of the Si single crystalline wafer and the gallium (Ga) atoms. The above-described Si re-melting region is representatively an AlN material layer grown in an MOCVD chamber by an in-situ process, but in addition, an AlN or AlNO material layer may be formed on the Si single crystalline wafer for a group III nitride power semiconductor growth substrate by in an ex-situ process before the Si single crystalline wafer is loaded in the MOCVD chamber using another external deposition (growth) process device (a sputtering, pulsed laser deposition (PLD), or atomic layer deposition (ALD) device). On the other hand, when the surface of the Si single crystalline wafer is damaged during the growth (deposition) of the AlN materials to form an electrically conductive interface through Si—Al metallic process reaction or when the AlN materials are grown (deposited) to a thickness of about 50 nm and crystal quality deteriorates during the growth of the GaN material-based power semiconductor active region, there is a risk of adverse effects that can promote a leakage current and an insulation breakdown in a vertical direction of the Si single crystalline wafer, and thus special care is required.

In addition, when a material is grown (or deposited), a process needs to be performed in consideration of a lattice constant (LC) and coefficient of thermal expansion (CTE), which are material-specific values between different materials, and when the LC and CTE between the two materials are significantly different, micro or macro cracks inevitably occur in the grown (deposited) material thin film or crystal quality deteriorates due to structural stress and thermo-mechanical induced stress occurring during or after the growth (deposition) process. In particular, when GaN materials are directly grown (deposited) on the Si single crystalline wafer for a group III nitride power semiconductor growth substrate, large tensile stress occurs simultaneously in terms of the LC and CTE, and thus cracks can be easily observed. Although various technologies have been disclosed as a method of relieving the above-described tensile stress or suppressing cracks, as a method of introducing a material and process that artificially generates compressive stress to compensate for tensile stress, a transition region for tensile stress relief, which suppresses cracking by stacking AlGaN materials containing a Al or Ga composition in a multilayered structure on the above-described Si re-melting prevention film region, is being introduced and used. However, when introducing and using the above-described AlGaN materials for tensile stress relief, there is still a limit to a sufficient increase in thickness, and it is still insufficient for improving the performance and quality of group III nitride power semiconductors.

In addition, the active region of the GaN material-based power semiconductor is typically formed by stacking four regions: 1) a GaN buffer layer (horizontal and vertical transistors), 2) a GaN channel layer (horizontal transistor) or a drift layer (vertical transistor), 3) an AlGaN barrier layer (horizontal transistor) or a p-type nitride semiconductor layer (vertical transistor), and 4) a capping passivation layer (horizontal transistor), a p-type nitride semiconductor layer (horizontal transistor), or a capping passivation layer (vertical transistor). However, to reduce crystal defects such as threading dislocations, regions 2) and 3) are preferably formed as thick as possible, such as 3 μm or more, but even when the above-described Si re-melting prevention film region and transition region for tensile stress relief are grown (deposited), a difference in CTE between the Si single crystalline wafer for a group III nitride power semiconductor growth substrate and the GaN materials is too large, making it difficult to indefinitely grow (deposit) to a predetermined thickness due to strong tensile stress.

Next, the conventional group III nitride semiconductor thin film materials and power semiconductor device structures using the same are grown and formed on an AlN ceramic template for a growth substrate, and in this case, the structure is formed by sequentially stacking a polycrystalline AlN ceramic substrate, an oxide bonding layer, a transferred single crystalline Si thin film (or thick film) layer, a Si re-melting prevention film region including AlN materials, a transition region for compressive stress relief, and an active region of a GaN material-based power semiconductor. Here, the polycrystalline AlN ceramic substrate uses a polycrystalline AlN (4.5 ppm) ceramic with a CTE similar to that of GaN to overcome a large difference in CTE between the Si single crystalline wafer (2.8 ppm) and the GaN (5.6 ppm) materials. In addition, the oxide bonding layer uses, as a bonding layer between wafer substrates, SiO2 materials whose physical properties and exterior shape are not changed for a long time in an MOCVD deposition or growth process chamber (high temperature reducing atmosphere).

In addition, the single crystalline Si thin film (or thick film) transferred onto the polycrystalline AlN ceramic substrate serves as a growth substrate for growing the active region of the GaN material-based power semiconductor, and to minimize the adverse effects due to the difference in CTE, the Si single crystalline wafer is sliced into a thinner thickness with a predetermined thickness and transferred, which is typically known as a smart-cut technology and is the same technology as a Si-on-insulator (SOI) and a piezoelectric-on-insulator (POI) to which a heterogeneous material wafer bonding technology using a hydrogen ion implant and a SiO2 wafer bonding layer is applied.

The above-described AlN ceramic template used as the growth substrate wafer for a GaN material-based thin film material and a power semiconductor device structure has a structure with a Si single crystalline thin film (or thick film) transferred onto a top layer and ultimately, basically requires the Si re-melting prevention film region and the transition region for tensile stress relief before the GaN material-based thin film materials and power semiconductor device structures using the same are grown like the above-described Si single crystalline wafer for a group III nitride power semiconductor growth substrate. However, although the type of material, composition, thickness, etc. in each region may be slightly different, main technical issues, such as tensile stress caused by re-melting and a difference in LC on the transferred Si single crystalline thin film (or thick film), are the same as those of the above-described Si single crystalline wafer for a group III nitride power semiconductor growth substrate. That is, disadvantages (thickness maximization, cracks) caused by the difference in CTE described in the conventional GaN material-based power semiconductor device based on the Si wafer for a growth substrate can be partially overcome using a polycrystalline AlN ceramic substrate whose CTE is similar to that of the GaN materials, but as in the case of the Si single crystalline wafer for a group III nitride power semiconductor growth substrate, high-density crystal defects caused by the difference in LC between Si and GaN materials and residual stress present in the active region of the GaN material-based power semiconductor still have not been resolved, resulting in serious quality problems.

### DISCLOSURE

### Technical Problem

The present invention has been made as a result of efforts to solve the conventional problems and is directed to providing a method of manufacturing a group III nitride semiconductor template and a semiconductor template manufactured using the same, in which a high-quality group III nitride semiconductor layer may be formed on a high heat dissipation support substrate with the same or similar lattice constant and coefficient of thermal expansion using a laser lift off (LLO) technique.

### Technical Solution

According to the present invention, the above object is achieved by a method of manufacturing a group III nitride semiconductor template, which includes a first operation of preparing a growth substrate and a support substrate, a second operation of growing a semiconductor layer on the growth substrate, a third operation of forming a first bonding layer on the semiconductor layer, a fourth operation of forming a second bonding layer on the support substrate, a fifth operation of bonding the first bonding layer and the second bonding layer to form a bonding layer, a sixth operation of separating the growth substrate from the semiconductor layer, and a seventh operation of forming a polarity transform layer for transforming a surface polarity of the semiconductor layer into a group III metal polarity on the semiconductor layer.

In addition, the sixth operation may include separating the growth substrate from the semiconductor layer using a laser lift off (LLO) technique.

In addition, the method according to the present invention may further include an eighth operation of growing an element active layer on the polarity transform layer.

In addition, the seventh operation may include etching the polarity transform layer to form a plurality of patterns.

In addition, the seventh operation may include etching the semiconductor layer to form a plurality of regular patterns and forming the polarity transform layer along the patterns of the semiconductor layer.

In addition, the seventh operation may include etching the semiconductor layer to form a plurality of irregular patterns, planarizing an end portion of each of the patterns, and then forming the polarity transform layer along the patterns of the semiconductor layer.

In addition, the first bonding layer and the second bonding layer may each include a bonding reinforcement layer configured to reinforce bonding with the support substrate or the semiconductor layer, a surface planarization layer configured to decrease a surface roughness of the support substrate or the semiconductor layer, and a bonding layer configured to bond the first bonding layer and the second bonding layer.

In addition, the support substrate may be a polycrystalline aluminum nitride (AlN) ceramic substrate.

According to the present invention, the above object is achieved by a method of manufacturing a group III nitride semiconductor template, which includes a first operation of preparing a growth substrate, a temporary substrate, and a support substrate, a second operation of growing a semiconductor layer on the growth substrate, a third operation of forming a first adhesive layer on the semiconductor layer, a fourth operation of forming a second adhesive layer on the temporary substrate, a fifth operation of attaching the first adhesive layer to the second adhesive layer to form an adhesive layer, a sixth operation of separating the growth substrate from the semiconductor layer, a seventh operation of converting a rough surface of the semiconductor layer, from which the growth substrate has been separated, into a mirror-like surface, an eighth operation of forming a first bonding layer on the semiconductor layer, a ninth operation of forming a second bonding layer on the support substrate, a tenth operation of bonding the first bonding layer and the second bonding layer to form a bonding layer, an eleventh operation of separating the temporary substrate from the adhesive layer, and a twelfth operation of separating the adhesive layer from the semiconductor layer.

In addition, the sixth operation may include separating the growth substrate from the semiconductor layer using an LLO technique, and the eleventh operation may include separating the temporary substrate from the adhesive layer using an LLO technique.

In addition, the method according to the present invention may further include a thirteenth operation of growing an element active layer on the semiconductor layer.

In addition, the seventh operation may include making the semiconductor layer have a mirror-like surface by forming planarization layer on the semiconductor layer and then planarizing the planarization layer.

In addition, the seventh operation may include making the semiconductor layer have a mirror-like surface by directly planarizing an upper surface of the semiconductor layer.

In addition, the seventh operation may include making the semiconductor layer have a mirror-like surface by etching an upper surface of the semiconductor layer to form a plurality of patterns, forming a first planarization layer along the patterns of the semiconductor layer, forming a second planarization layer on the first planarization layer, and planarizing the first planarization layer or the second planarization layer.

In addition, the first bonding layer and the second bonding layer may each include a bonding reinforcement layer configured to reinforce bonding with the support substrate or the semiconductor layer, a surface planarization layer configured to decrease a surface roughness of the support substrate or the semiconductor layer, and a bonding layer configured to bond the first bonding layer and the second bonding layer.

In addition, the support substrate may be a polycrystalline aluminum nitride (AlN) ceramic substrate.

According to the present invention, the above object is achieved by a group III nitride semiconductor template manufactured by the method of manufacturing a group III nitride semiconductor template.

### Advantageous Effects

According to the present invention, since a high heat dissipation support substrate with a coefficient of thermal expansion (CTE) that is the same as or similar to that of a group III nitride semiconductor layer and a group III nitride single crystalline growth layer for a high-quality group III nitride thin film material and power semiconductor device structure growth using the same can be coupled through a high heat-resistant bonding layer, a high-quality group III nitride semiconductor layer can be formed at a high temperature of 700° C. or higher. That is, since the group III nitride thin film material and the power semiconductor device structure using the same and the support substrate can have the same or similar lattice constant and CTE, it is possible to minimize structural stress and thermo-mechanical induced stress occurring during growth.

In addition, according to the present invention, since the high heat dissipation support substrate is made of a polycrystalline ceramic, there is an advantage in that the high heat dissipation support substrate is better than a single crystalline ceramic in terms of cost competitiveness.

Meanwhile, the effects of the present invention are not limited to the above-described effects, and may include various effects within a range that is apparent to those skilled in the art from the following descriptions.

### DESCRIPTION OF DRAWINGS

FIG. 1 shows a semiconductor template manufactured by a method of manufacturing a group III nitride semiconductor template according to first to fourth embodiments of the present invention.

FIG. 2 shows that an element active layer is grown on the semiconductor template manufactured by the method of manufacturing a group III nitride semiconductor template according to the first to fourth embodiments of the present invention.

FIG. 3 is a flowchart of a method of manufacturing a group III nitride semiconductor template according to the first embodiment of the present invention.

FIG. 4 shows a process of manufacturing a semiconductor template according to the method of manufacturing a group III nitride semiconductor template according to the first embodiment of the present invention.

FIG. 5 is a flowchart of the method of manufacturing a group III nitride semiconductor template according to the second embodiment of the present invention.

FIG. 6 shows a process of manufacturing a semiconductor template according to the method of manufacturing a group III nitride semiconductor template according to the second embodiment of the present invention.

FIG. 7 is a flowchart of the method of manufacturing a group III nitride semiconductor template according to the third embodiment of the present invention.

FIG. 8 is a flowchart of the method of manufacturing a group III nitride semiconductor template according to the fourth embodiment of the present invention.

FIG. 9 shows in detail a first bonding layer and a second bonding layer that are manufactured by the method of manufacturing a group III nitride semiconductor template according to the first to fourth embodiments of the present invention.

FIG. 10 shows a first case of the seventh operation in the method of manufacturing a semiconductor template according to the first or third embodiment of the present invention.

FIG. 11 shows a second case of the seventh operation in the method of manufacturing a semiconductor template according to the first or third embodiment of the present invention.

FIG. 12 show a third case of the seventh operation in the method of manufacturing a semiconductor template according to the first or third embodiment of the present invention.

FIG. 13 shows a first case of the seventh operation in the method of manufacturing a semiconductor template according to the second or fourth embodiment of the present invention.

FIG. 14 shows a second case of the seventh operation in the method of manufacturing a semiconductor template according to the second or fourth embodiment of the present invention.

FIG. 15 show a third case of the seventh operation in the method of manufacturing a semiconductor template according to the second or fourth embodiment of the present invention.

FIG. 16 shows a third case of the seventh operation in the method of manufacturing a semiconductor template according to the first or third embodiment of the present invention, in which a degree of planarization is adjusted in three cases.

### MODES OF THE INVENTION

Hereinafter, some embodiments of the present invention will be described in detail with reference to exemplary drawings. In adding reference numerals to components in each drawing, it should be noted that the same components have the same reference numerals as much as possible even when they are illustrated in different drawings.

In addition, in describing embodiments of the present invention, detailed descriptions of related known configurations or functions will be omitted when it is determined that the detailed descriptions obscure the understanding of the embodiments of the present invention.

In addition, terms such as first, second, A, B, (a), and (b) may be used to describe components of the embodiments of the present invention. These terms are only for the purpose of distinguishing one component from another component, and the nature, sequence, order, or the like of the corresponding component is not limited by the terms.

A method S100 of manufacturing a group III nitride semiconductor template according to the first embodiment of the present invention will now be described in detail with reference to the accompanying drawings.

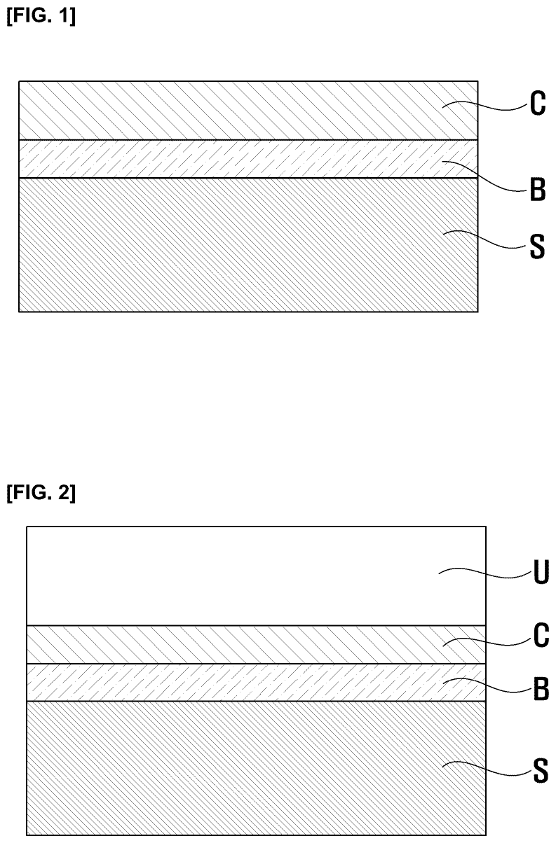

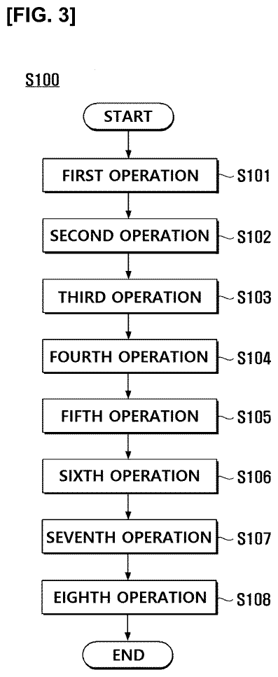

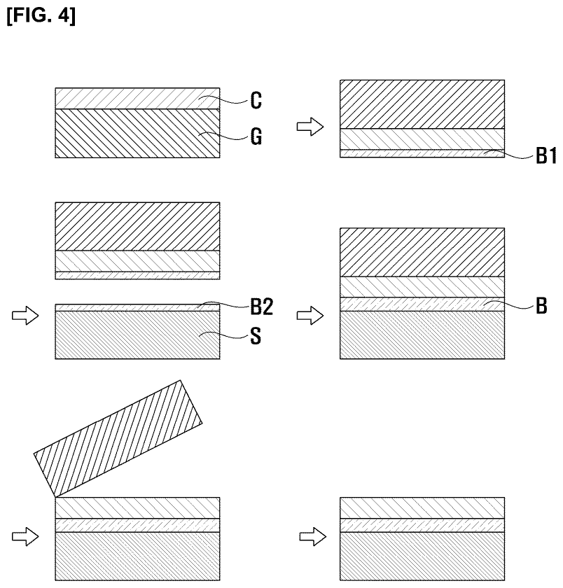

FIG. 1 shows a semiconductor template manufactured by a method of manufacturing a group III nitride semiconductor template according to first to fourth embodiments of the present invention, FIG. 2 shows that an element active layer is grown on the semiconductor template manufactured by the method of manufacturing a group III nitride semiconductor template according to the first to fourth embodiments of the present invention, FIG. 3 is a flowchart of a method of manufacturing a group III nitride semiconductor template according to the first embodiment of the present invention, and FIG. 4 shows a process of manufacturing a semiconductor template according to the method of manufacturing a group III nitride semiconductor template according to the first embodiment of the present invention.

As shown in FIGS. 1 to 4, the method S100 of manufacturing a group III nitride semiconductor template according to the first embodiment of the present invention relates to a method of manufacturing a semiconductor template in which polarities of a surface of a group III nitride semiconductor layer C initially grown on a growth substrate G and a surface of a group III nitride semiconductor layer C finally formed on a support substrate S are different (i.e., opposite) and includes a first operation S101, a second operation S102, a third operation S103, a fourth operation S104, a fifth operation S105, a sixth operation S106, a seventh operation S107, and an eighth operation S108.

The first operation S101 is an operation of preparing the growth substrate G and the support substrate S.

The growth substrate G is an optically transparent substrate through which a laser (single wavelength light) beam is 100% transmitted (theoretically) without absorption after the group III nitride semiconductor layer C is grown, and in the present disclosure, is limited to a single crystalline sapphire material-based (Al2O3, ScAlMgO4) substrate containing aluminum oxide (Al2O3).

The support substrate S is a substrate that supports the group III nitride semiconductor layer C and a group III nitride semiconductor element active layer U after undergoing each operation of the method S100 of manufacturing a group III nitride semiconductor template according to the first embodiment of the present invention, and the support substrate S may be formed of a multilayered structure and a material that has high heat dissipation performance (60 W/mK or more) and a coefficient of thermal expansion (CTE, ppm) less than or equal to that of the group III nitride semiconductor layer C, and formed in a polycrystalline or single crystalline microstructure.

More specifically, the support substrate S may contain at least one material selected from materials including silicon (Si), silicon carbide (SiC), silicon nitride (SiNx), aluminum nitride (AlN), and gallium nitride (GaN). Here, the heat dissipation performance of silicon (Si) is 149 W/mK, the heat dissipation performance of silicon carbide (SiC) ranges from 300 to 450 W/mK, the heat dissipation performance of silicon nitride (SiNx) is 90 W/mK, the heat dissipation performance of aluminum nitride (AlN) ranges from 170 to 230 W/mK, and the heat dissipation performance of gallium nitride (GaN) ranges from 170 to 210 W/mK, and the CTE of silicon (Si) is 2.6 ppm, the CTE of silicon carbide (SiC) is 4.8 ppm, the CTE of silicon nitride (SiNx) is 3.7 ppm, the CTE of aluminum nitride (AlN) is 4.5 ppm, and the CTE of gallium nitride (GaN) is 5.6 ppm, which are each suitable for a material of the high heat dissipation support substrate S. In addition, the silicon (Si), silicon carbide (SiC), silicon nitride (SiNx), aluminum nitride (AlN), or gallium nitride (GaN) support substrate S is preferably formed in a polycrystalline microstructure through a high-temperature sintering process rather than a single crystalline microstructure wafer, and thus there is an advantage in that it is possible to secure cost competitiveness.

The second operation S102 is an operation of growing the group III nitride semiconductor layer C on the growth substrate G as a single layer or multiple layers.

Here, it is preferable that the group III nitride semiconductor layer C basically has dopant-free electrical insulation properties, but in some cases, has electrical conduction properties including a dopant as a means for minimizing crystal defects and serves as a seed for growing the group III nitride thin film material and the power semiconductor device structure using the same.

Here, since a surface of the group III nitride semiconductor layer C formed on the growth substrate G and a surface of the group III nitride semiconductor layer C transferred onto the support substrate S are inverted, it is preferable to form a microstructure by treating a surface of the growth substrate G so that a predetermined surface of the semiconductor layer C may be preferably formed. For example, in the case of a gallium nitride (GaN) semiconductor layer C, a gallium polarity (Ga-polarity) or nitrogen polarity (N-polarity) surface may be selectively controlled according to the surface treatment and growth conditions of the growth substrate G. Typically, when the group III nitride semiconductor layer C is grown on a sapphire growth substrate wafer in an MOCVD chamber, while the group III nitride semiconductor layer C has a surface with a metal (M: Ga, Al, In) polarity with 3 valence electrons, an interface in direct contact with the sapphire growth substrate has a nitrogen polarity with 5 valence electrons.

The third operation S103 is an operation of forming a first bonding layer B1 on the group III nitride semiconductor layer C. Here, the first bonding layer B1 may contain a metal such as aluminum (Al), tungsten (W), or molybdenum (Mo) or an alloy thereof, silicon oxide (SiOx), silicon nitride (SiNx), aluminum oxide (Al2O3), aluminum nitride (AlN), aluminum gallium nitride (AlGaN), gallium nitride (GaN), indium gallium nitride (InGaN), indium nitride (InN), amorphous or polycrystalline silicon (Si), zinc oxide (ZnO), C60 (fullerene), or furthermore, may additionally contain a flowable oxide (FOX) such as spin-on-glass (SOG) or hydrogen silsesquioxane (HSQ) to improve surface roughness. In particular, it is preferable to use a chemical vapor deposition (CVD) process such as an MOCVD or atomic layer deposition (ALD) process for aluminum nitride (AlN), aluminum gallium nitride (AlGaN), gallium nitride (GaN), indium gallium nitride (InGaN), and indium nitride (InN) materials.

The third operation S104 is an operation of forming a second bonding layer B2 on the support substrate S. Here, the second bonding layer B2 may contain a metal such as aluminum (Al), tungsten (W), or molybdenum (Mo) or an alloy thereof, silicon oxide (SiOx), silicon nitride (SiNx), aluminum oxide (Al2O3), aluminum nitride (AlN), aluminum gallium nitride (AlGaN), gallium nitride (GaN), indium gallium nitride (InGaN), indium nitride (InN), amorphous or polycrystalline silicon (Si), zinc oxide (ZnO), C60 (fullerene), or furthermore, may additionally contain a flowable oxide (FOx) such as SOG or hydrogen silsesquioxane (HSQ) to improve surface roughness. In particular, it is preferable to use a CVD process such as an MOCVD or ALD process for aluminum nitride (AlN), aluminum gallium nitride (AlGaN), gallium nitride (GaN), indium gallium nitride (InGaN), and indium nitride (InN) materials.

Meanwhile, the first bonding layer B1 and the second bonding layer B2 may each include a bonding reinforcement layer R, a surface planarization layer F, and a bonding layer J.

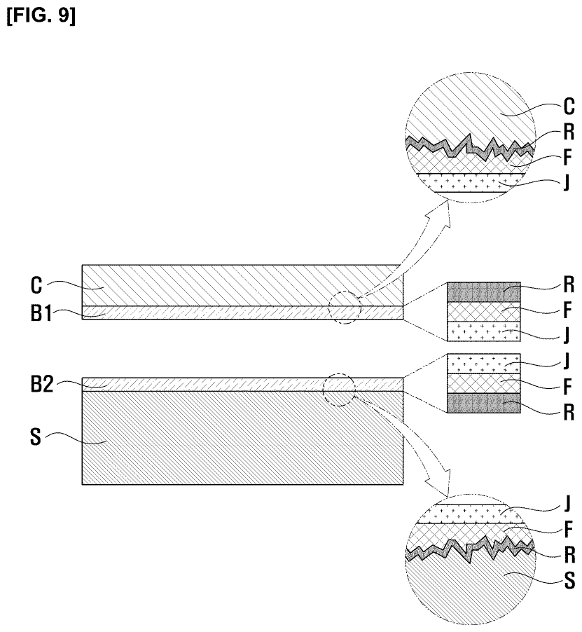

FIG. 9 shows in detail the first bonding layer B1 and the second bonding layer B2 that are manufactured by the method of manufacturing a group III nitride semiconductor template according to the first to fourth embodiments of the present invention.

As shown in FIG. 9, the bonding reinforcement layer R is formed to reinforce bonding with the group III nitride semiconductor layer C (in the case of the first bonding layer B1) or the support substrate S (in the case of the second bonding layer B2), and the bonding reinforcement layer R may contain, for example, silicon oxide (SiOx), silicon nitride (SiNx), chromium (Cr), titanium (Ti), molybdenum (Mo), or HMDS.

The surface planarization layer F is formed to decrease the surface roughness of the group III nitride semiconductor layer C or the support substrate S, and the surface planarization layer F may contain, for example, silicon oxide (SiOx), silicon nitride (SiNx), aluminum oxide (Al2O3), aluminum nitride (AlN), or amorphous or polycrystalline silicon (Si) to improve surface roughness. Furthermore, the surface planarization layer F may additionally contain a flowable oxide (FOx) such as SOG and HSQ.

The bonding layer J is formed to bond the first bonding layer B1 and the second bonding layer B2, may be made of a permanent bonding material, may contain a metal such as aluminum (Al), tungsten (W), or molybdenum (Mo) or an alloy thereof, silicon oxide (SiOx), silicon nitride (SiNx), aluminum oxide (Al2O3), aluminum nitride (AlN), aluminum gallium nitride (AlGaN), gallium nitride (GaN), indium gallium nitride (InGaN), indium nitride (InN), amorphous or polycrystalline silicon (Si), zinc oxide (ZnO), C60 (fullerene), or furthermore, may additionally contain a flowable oxide (FOx) such as SOG or hydrogen silsesquioxane (HSQ) to improve surface roughness. In particular, it is preferable to use a CVD process such as an MOCVD or ALD process for aluminum nitride (AlN), aluminum gallium nitride (AlGaN), gallium nitride (GaN), indium gallium nitride (InGaN), and indium nitride (InN) materials.

Meanwhile, the bonding reinforcement layer R and the surface planarization layer F may be selectively introduced or omitted according to a process, and when the bonding reinforcement layer R and the surface planarization layer F are omitted according to the process, the bonding layer J may be directly deposited on the group III nitride semiconductor layer C (in the case of the first bonding layer B1) or the support substrate S (in the case of the second bonding layer B2).

The fifth operation S105 is an operation of forming the bonding layer B by bonding the first bonding layer B1 and the second bonding layer B2. That is, the fifth operation S105 is an operation of turning over the growth substrate G on which the first bonding layer B1 has been formed (deposited) and pressing and bonding the growth substrate G to the support substrate S on which the second bonding layer B2 has been formed at a temperature of lower than 300° C.

Normally, to minimize wafer bowing after bonding, it is optimal to select the material of the support substrate S so that a difference in CTE with the growth substrate G may be less than 2 ppm, but the support substrate S containing Si, SiC, SiNx, AlN, and GaN, which have high heat dissipation performance, has a difference in CTE of 2 ppm or more from the sapphire growth substrate G, realistically making it difficult to bond the wafer at a high temperature. In this case, it is possible to minimize stress by setting a bonding process temperature to about room temperature and performing the process, thereby preventing wafer bowing.

The sixth operation S106 is an operation of separating the optically transparent growth substrate G from the group III nitride semiconductor layer C using a laser lift off (LLO) technique. Here, the LLO technique is a technique of separating an epitaxy-grown layer from the growth substrate G by irradiating a back surface of the transparent growth substrate G with an ultraviolet (UV) laser beam having a uniform optical output and beam profile and a single wavelength. Then, a damaged region, contaminated surface residue, and low-quality single crystalline thin film region due to the separation of the growth substrate G can be removed as completely as possible.

The seventh operation S107 is an operation of reinforcing the weak bonding layer B formed between the first bonding layer B1 and the second bonding layer B2 by forming a polarity transform layer W for transforming a surface polarity of the group III nitride semiconductor layer C from a nitrogen polarity (N-polarity) to a group III metal polarity (M(Ga, Al, In)-polarity) before growing the group III nitride semiconductor element active layer U on the group III nitride semiconductor layer C and annealing the group III nitride semiconductor layer C from which the growth substrate G has been separated at a high temperature of 700° C. or higher. In some cases, the order of the process of forming the polarity transform layer W for transforming the surface polarity and the high-temperature annealing process for reinforcing the bonding layer B may be changed.

As described above, the widely commercialized transparent growth substrate G is sapphire, and when the group III nitride semiconductor layer C is grown on the sapphire growth substrate G in an MOCVD chamber, while the group III nitride semiconductor layer C has a surface with a metal (M: Ga, Al, In) polarity with 3 valence electrons, an interface in direct contact with the sapphire growth substrate has a nitrogen polarity with 5 valence electrons. Therefore, the surface polarity of the group III nitride semiconductor layer C finally formed on the support substrate S has a nitrogen polarity (N-polarity) surface unlike the metal polarity (M-polarity) surface grown on the sapphire growth substrate G. However, there is a serious technical difficulty in securing high quality when growing the stacked structure of the group III nitride semiconductor element active layer U on such a nitrogen polarity surface, and furthermore, even when growth is possible, there is a disadvantage that a growth rate is very low. That is, to implement the high-quality group III nitride semiconductor element active layer U, a process of transforming the surface polarity of the group III nitride semiconductor layer C formed on the support substrate S so that the surface of the group III nitride semiconductor layer C necessarily has the group III metal polarity (M (Al, Ga, In)-polarity) rather than the nitrogen polarity should be introduced.

To this end, the seventh operation S107 includes, after separating the growth substrate G and before loading the Si single crystalline wafer in the MOCVD chamber, depositing or growing the polarity transform layer W that promotes the group III metal (M) polarity such as aluminum (Al), aluminum nitride (AIN), or aluminum nitride oxide (AINO) on the group III nitride semiconductor layer C with the nitrogen polarity surface through a physical vapor deposition (PVD) (sputtering, pulsed laser deposition (PLD), molecular beam epitaxy (MBE), or evaporator) process. Thereafter, in the eighth operation S108 to be described below, the element active layer U is grown on an upper surface of the polarity transform layer W.

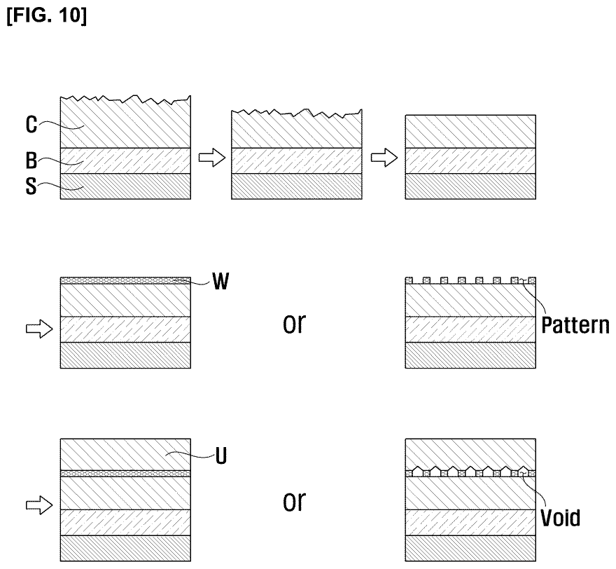

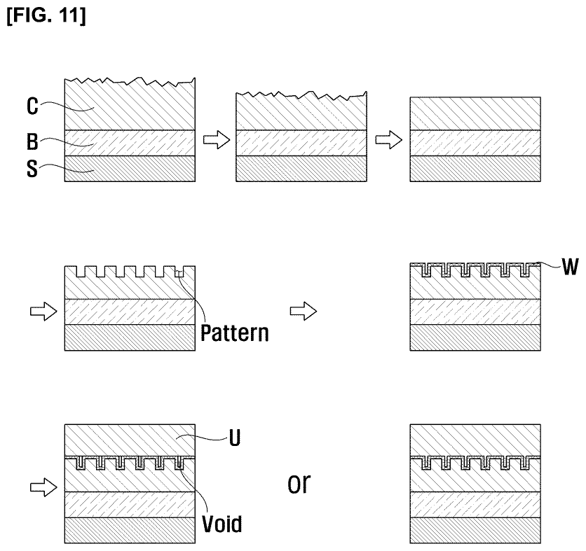

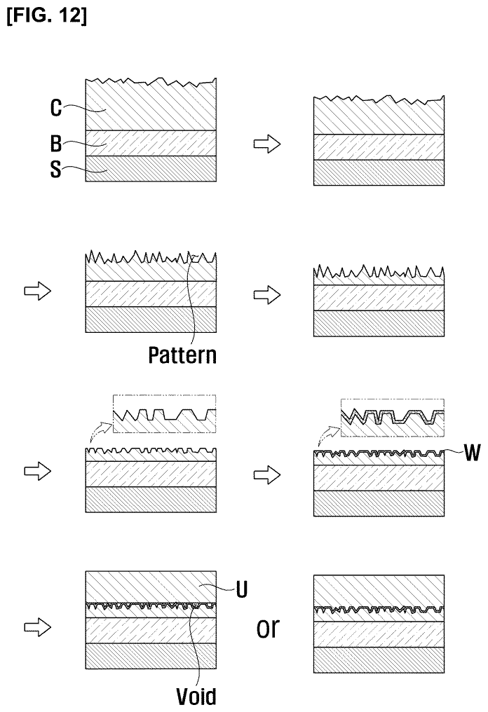

FIG. 10 shows a first case of the seventh operation in the method of manufacturing a semiconductor template according to the first or third embodiment of the present invention, FIG. 11 shows a second case of the seventh operation in the method of manufacturing a semiconductor template according to the first or third embodiment of the present invention, and FIG. 12 show a third case of the seventh operation in the method of manufacturing a semiconductor template according to the first or third embodiment of the present invention.

Meanwhile, as shown in FIG. 10, the first case of the seventh operation S107 will now be described. In the first case, after the growth substrate G is separated in the sixth operation S106, an upper surface of the group III nitride semiconductor layer C is selectively (meaning that the process may be omitted as needed) dry-etched, and then the upper surface of the nitride semiconductor layer C is selectively planarized through a chemical mechanical polishing (CMP) process. Then, the polarity transform layer W that promotes the group III metal polarity (M-polarity) such as aluminum (Al), aluminum nitride (AlN), aluminum nitride oxide (AlNO), gallium (Ga), gallium nitride (GaN), gallium nitride oxide (GaNO), indium (In), indium nitride (InN), and indium nitride oxide (InNO) on the group III nitride semiconductor layer C with the nitrogen polarity surface is deposited or grown through the PVD (sputtering, PLD, MBE, or evaporator) process, and in this case, various patterns may be formed by etching the deposited or grown polarity transform layer W, the etched pattern may be regular or irregular, and a shape, size, spacing, and height are not limited. Then, in the eighth operation S108 to be described below, the element active layer U may be grown on an upper surface of the polarity transform layer W, and when the pattern is formed by etching the polarity transform layer W, multiple voids may be formed at an interface between the polarity transform layer W and the element active layer U in contact with the same. The voids have an effect of relieving the stress of the re-grown group III nitride semiconductor layer C.

Meanwhile, as shown in FIG. 11, a second case of the seventh operation S107 will now be described. In the second case, after the growth substrate G is separated in the sixth operation S106, the upper surface of the group III nitride semiconductor layer C is selectively (meaning that the process may be omitted as needed) dry-etched, and then the upper surface of the nitride semiconductor layer C is selectively planarized through a CMP process. Then, various patterns may be formed by etching the upper surface of the group III nitride semiconductor layer C, and the etched pattern may be regular or irregular, and the shape, size, spacing, height, etc. are not limited. Then, the polarity transform layer W that promotes the group III metal polarity (M-polarity) such as aluminum (Al), aluminum nitride (AlN), aluminum nitride oxide (AlNO), gallium (Ga), gallium nitride (GaN), gallium nitride oxide (GaNO), indium (In), indium nitride (InN), and indium nitride oxide (InNO) on the group III nitride semiconductor layer C on which the patterns of the nitrogen polarity surface have been etched is deposited or grown along the patterns of the group III nitride semiconductor layer C through the PVD (sputtering, PLD, MBE, evaporator) process. Then, in the eighth operation S108 to be described below, the element active layer U may be grown on the upper surface of the polarity transform layer W, and as needed, the element active layer U may be grown to fill the etched pattern to prevent voids from being formed therein, or the element active layer U may be grown so that the etched patterns are not filled to form voids therein. The voids have an effect of relieving the stress of the re-grown group III nitride semiconductor layer C.

Meanwhile, as shown in FIG. 12, a third case of the seventh operation S107 will now be described. In the third case, after the growth substrate G is separated in the sixth operation S106, the upper surface of the group III nitride semiconductor layer C is selectively (meaning that the process may be omitted as needed) dry-etched. Then, various patterns may be formed by etching the upper surface of the group III nitride semiconductor layer C, and the etched pattern may be regular or irregular, and the shape, size, spacing, height, etc. are not limited. Then, after the upper surface of the group III nitride semiconductor layer C on which the patterns have been etched is selectively dry-etched, an end portion of each of the patterns is planarized (peak planarization) through a PR mask or CMP process. For example, after forming patterns by surface-texturing the group III nitride semiconductor layer C with the nitrogen polarity surface with a basic solution containing an OH component, a peaked part of a hexagonal pyramid-shaped surface formed by surface texturing may be planarized to have a flat plateau shape through a plasma dry process as a subsequent process. Then, the polarity transform layer W that promotes the group III metal polarity (M-polarity) such as aluminum (Al), aluminum nitride (AlN), aluminum nitride oxide (AlNO), gallium (Ga), gallium nitride (GaN), gallium nitride oxide (GaNO), indium (In), indium nitride (InN), and indium nitride oxide (InNO) on the group III nitride semiconductor layer C on which the patterns of the nitrogen polarity surface have been etched is deposited or grown along the patterns of the group III nitride semiconductor layer C through a PVD (sputtering, PLD, MBE, evaporator) process. Then, in the eighth operation S108 to be described below, the element active layer U may be grown on the upper surface of the polarity transform layer W, and as needed, the element active layer U may be grown to fill the etched pattern to prevent voids from being formed therein, or the element active layer U may be grown so that the etched patterns are not filled to form voids therein. The voids have an effect of relieving the stress of the re-grown group III nitride semiconductor layer C.

The eighth operation S108 is an operation of growing the group III nitride semiconductor element active layer U on the group III nitride semiconductor layer C. That is, through the previous operations, a semiconductor element active layer U structure containing a desired compound may be finally grown on the upper surface of the group III nitride semiconductor layer C formed on the high heat dissipation support substrate S. For example, in the case of the GaN material-based power semiconductor structure, the element active layer U may be typically formed by stacking four regions: 1) a GaN buffer layer (horizontal and vertical transistors), 2) a GaN channel layer (horizontal transistor) or a drift layer (vertical transistor), 3) an AlGaN barrier layer (horizontal transistor) or a p-type nitride semiconductor layer (vertical transistor), and 4) a capping passivation layer (horizontal transistor), a p-type nitride semiconductor layer (horizontal transistor), or a capping passivation layer (vertical transistor).

According to the method S100 of manufacturing a group III nitride semiconductor template according to the first embodiment of the present invention, which includes the first operation S101, the second operation S102, the third operation S103, the fourth operation S104, the fifth operation S105, the sixth operation S106, the seventh operation S107, and the eighth operation S108, and the group III nitride semiconductor template manufactured using the same, the high heat dissipation support substrate S with a CTE that is the same as or similar to that of the group III nitride semiconductor layer C and the group III nitride single crystalline growth layer for the high-quality group III nitride thin film material and the power semiconductor device structure growth using the same may be bonded through a high heat-resistant bonding layer, thereby enabling the formation of a high-quality group III nitride semiconductor layer at a high temperature of 700° C. or higher. That is, since the group III nitride thin film material and the power semiconductor device structure using the same and the support substrate can have the same or similar lattice constant and CTE, it is possible to minimize structural stress and thermo-mechanical induced stress occurring during growth.

In addition, according to the present invention, since the pattern P may be etched to a preset depth on the group III nitride semiconductor layer C or the bonding layer B, it is advantageous for the wafer bonding process. That is, in the case of direct wafer bonding, it is quite sensitive to the surface roughness of the surface on which the wafer is bonded and wafer bowing, but according to the patterning of the present invention, there is an advantage in that the strict wafer surface roughness and bowing issue can be considerably alleviated. In addition, according to the patterning of the present invention, since gas generated inside the bonding layer B during the wafer bonding process can be easily discharged, the bonding strength of the bonding layer B can be reinforced in a void-free manner, and structural stress and thermo-mechanical induced stress can also be more effectively buffered.

In addition, according to the present invention, since the high heat dissipation support substrate S is made of a polycrystalline ceramic, there is an advantage in that the high heat dissipation support substrate is better than a single crystalline ceramic in terms of cost competitiveness.

In addition, according to the present invention, although the polarity of the surface of the group III nitride semiconductor layer C initially grown on the growth substrate G and the polarity of the surface of the semiconductor layer C finally formed on the support substrate S are different (i.e., opposite), before growing the group III nitride semiconductor element active layer U, a material layer that promotes group III metal polarity (M-polarity) may be introduced to grow the high-quality group III nitride semiconductor element active layer U.

A method S200 of manufacturing a group III nitride semiconductor template according to the second embodiment of the present invention will now be described in detail with reference to the accompanying drawings.

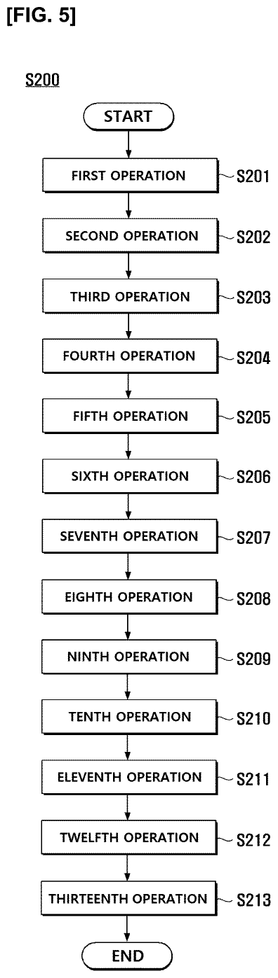

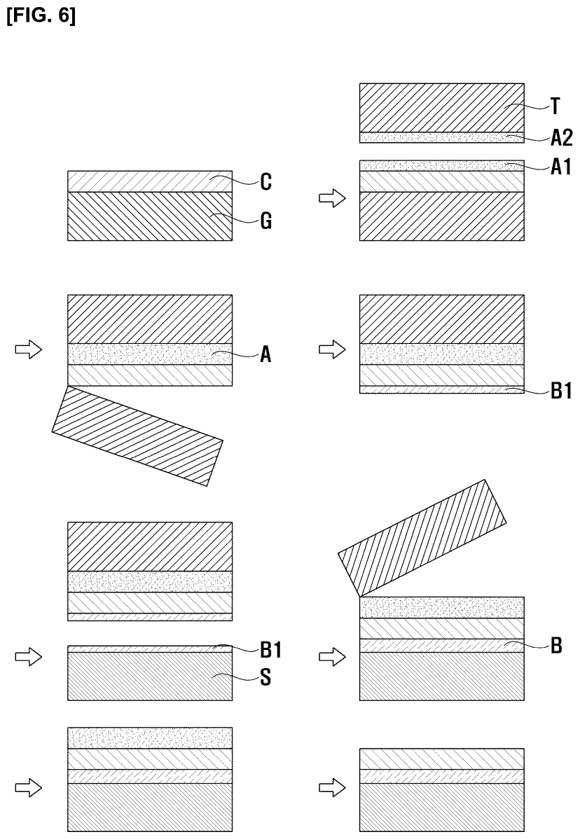

FIG. 1 shows a semiconductor template manufactured by a method of manufacturing a group III nitride semiconductor template according to first to fourth embodiments of the present invention, FIG. 2 shows that an element active layer is grown on the semiconductor template manufactured by the method of manufacturing a group III nitride semiconductor template according to the first to fourth embodiments of the present invention, FIG. 5 is a flowchart of the method of manufacturing a group III nitride semiconductor template according to the second embodiment of the present invention, and FIG. 6 shows a process of manufacturing a semiconductor template according to the method of manufacturing a group III nitride semiconductor template according to the second embodiment of the present invention.

As shown in FIGS. 1, 2, 5, and 6, the method S200 of manufacturing a group III nitride semiconductor template according to the second embodiment of the present invention relates to a method of manufacturing a group III nitride semiconductor template in which polarities of the surface of the group III nitride semiconductor layer C initially grown on the growth substrate G and the surface of the group III nitride semiconductor layer C finally formed on the support substrate S are the same and includes a first operation S201, a second operation S202, a third operation S203, a fourth operation S204, a fifth operation S205, a sixth operation S206, a seventh operation S207, an eighth operation S208, a ninth operation S209, a tenth operation S210, an eleventh operation S211, a twelfth operation S212, and a thirteenth operation S213.

The first operation S201 is an operation of preparing the growth substrate G, a temporary substrate T, and the support substrate S.

The growth substrate G is an optically transparent substrate through which a laser (single wavelength light) beam is 100% transmitted (theoretically) without absorption after the group III nitride semiconductor layer C is grown, and in the present disclosure, is limited to a single crystalline sapphire material-based (Al2O3, ScAlMgO4) substrate containing aluminum oxide (Al2O3).

The support substrate S is a substrate that supports the group III nitride semiconductor layer C and the group III nitride semiconductor element active layer U after undergoing each operation of the method S200 of manufacturing a group III nitride semiconductor template according to the second embodiment of the present invention, and the support substrate S may be formed of a multilayered structure and a material that has high heat dissipation performance (60 W/mK or more) and a CTE (ppm) less than or equal to that of the group III nitride semiconductor layer C, and formed in a polycrystalline or single crystalline microstructure.

More specifically, the support substrate S may contain at least one material selected from materials including silicon (Si), silicon carbide (SiC), silicon nitride (SiNx), aluminum nitride (AlN), and gallium nitride (GaN). Here, the heat dissipation performance of silicon (Si) is 149 W/mK, the heat dissipation performance of silicon carbide (SiC) ranges from 300 to 450 W/mK, the heat dissipation performance of silicon nitride (SiNx) is 90 W/mK, the heat dissipation performance of aluminum nitride (AlN) ranges from 170 to 230 W/mK, and the heat dissipation performance of gallium nitride (GaN) ranges from 170 to 210 W/mK, and the CTE of silicon (Si) is 2.6 ppm, the CTE of silicon carbide (SiC) is 4.8 ppm, the CTE of silicon nitride (SiNx) is 3.7 ppm, the CTE of aluminum nitride (AlN) is 4.5 ppm, and the CTE of gallium nitride (GaN) is 5.6 ppm, which are each suitable for a material of the high heat dissipation support substrate S. In addition, the silicon (Si), silicon carbide (SiC), silicon nitride (SiNx), aluminum nitride (AlN), and gallium nitride (GaN) support substrate S is preferably formed in a polycrystalline microstructure through a high-temperature sintering process rather than a single crystalline microstructure wafer, and thus there is an advantage in that it is possible to secure cost competitiveness.

The temporary substrate T is made of a material that has a CTE that is the same as or similar to that of the growth substrate G and at the same time, optically transparent, and it is preferable that a difference in CTE does not exceed a maximum of 2 ppm. The most preferable temporary substrate T material that satisfies the above may include sapphire used as the group III nitride semiconductor growth substrate G or glass whose CTE has been adjusted to have a difference of 2 ppm or less from the growth substrate G.

The second operation S202 is an operation of growing the group III nitride semiconductor layer C on the growth substrate G as a single layer or multiple layers.

Here, it is preferable that the group III nitride semiconductor layer C basically has dopant-free electrical insulation properties, but in some cases, has electrical conduction properties including a dopant as a means for minimizing crystal defects and serves as a seed for growing the group III nitride thin film material and the power semiconductor device structure using the same.

Here, since a surface of the group III nitride semiconductor layer C formed on the growth substrate G and a surface of the group III nitride semiconductor layer C transferred onto the support substrate S are inverted, it is preferable to form a microstructure by treating a surface of the growth substrate G so that a predetermined surface of the semiconductor layer C may be preferably formed. For example, in the case of a gallium nitride (GaN) semiconductor layer C, a gallium polarity (Ga-polarity) or nitrogen polarity (N-polarity) surface may be selectively controlled according to the surface treatment and growth conditions of the growth substrate G. Typically, when the group III nitride semiconductor layer C is grown on a sapphire growth substrate wafer in an MOCVD chamber, while the group III nitride semiconductor layer C has a surface with a metal (M: Ga, Al, In) polarity with 3 valence electrons, an interface in direct contact with the sapphire growth substrate has a nitrogen polarity with 5 valence electrons.

The third operation S203 is an operation of forming a first adhesive layer A1 on the group III nitride semiconductor layer C.

Here, before forming the first adhesive layer A1 on the group III nitride semiconductor layer C, it is preferable to deposit or coat a protective layer to prevent the semiconductor layer C from being damaged during a subsequent process. A material for this purpose may include, for example, oxides including SiO2, nitrides including SiNx, etc.

The fourth operation S204 is an operation of forming a second adhesive layer A2 on the temporary substrate T.

Here, the optically transparent temporary substrate T is a substrate that is ultimately easily separated by the LLO technique in the subsequent process, and it is essential to deposit an LLO sacrificial layer on the temporary substrate T before forming the second adhesive layer A2. As needed, a bonding reinforcement layer may be separately provided before the LLO sacrificial layer is deposited so that an LLO sacrificial layer material may be strongly bonded to an upper portion of the temporary substrate T. In this case, the bonding reinforcement layer may preferentially contain, for example, an oxide including SiO2, a nitride including SiNx, etc., which are optically transparent materials when a laser beam is radiated. In addition, the above-described LLO sacrificial layer material may include an oxide, a nitride, etc., which may be deposited by a PVD technique such as a sputtering, PLD, or evaporator technique.

Here, the first adhesive layer A1 and the second adhesive layer A2 may include a flowable oxide (FOX) such as benzocyclobuene (BCB), a SU-8 polymer, SOG, or HSQ for improving surface roughness, etc.

The fifth operation S205 is an operation of forming the adhesive layer A by attaching the first adhesive layer A1 to the second adhesive layer A2. That is, the fifth operation S205 is an operation of turning over the temporary substrate T on which the second adhesive layer A2 has been formed and pressing and bonding the temporary substrate T to the growth substrate G on which the first adhesive layer A1 has been formed at a temperature of lower than 300° C.

The sixth operation S206 is an operation of separating the optically transparent growth substrate G from the group III nitride semiconductor layer C using an LLO technique. Here, the LLO technique is a technique of separating an epitaxy-grown layer from the growth substrate G by irradiating a back surface of the transparent growth substrate G with an ultraviolet (UV) laser beam having a uniform optical output and beam profile and a single wavelength. Then, a damaged region, contaminated surface residue, and low-quality single crystalline thin film region due to the separation of the growth substrate G can be removed as completely as possible.

The seventh operation S207 is an operation of converting a rough surface due to a laser damage area caused by the above-described LLO process, an inversion domain (ID) and inversion domain boundary (IDB) that are inherently present, etc., into a mirror-like surface before forming the first bonding layer B1 on the group III nitride semiconductor layer C.

The nitrogen polarity (N-polarity) surface from which the growth substrate G has been separated by the LLO technique has not only laser damage parts due to the instability of the laser beam and contamination of the back surface of the growth substrate G, but also has surface regions with inherent group III metal polarity (M-polarity) sporadically distributed in a region adjacent to the growth substrate G even when there is a difference in amount when the group III nitride semiconductor layer C is initially grown on the growth substrate G. A dominant polarity in the above-described region adjacent to the growth substrate G is basically nitrogen (N), but the sporadically distributed group III metal (M) polarity region is referred to as the inversion domain (ID), and at the same time, a boundary between a nitrogen (N) polarity plane and a group III metal polarity region (ID) plane in contact therewith in a thickness (growth) direction of the group III nitride semiconductor layer C is referred to as the inversion domain boundary (IDB). In particular, the nitrogen (N) polarity surface has a characteristic that it is chemically very unstable compared to the group III metal (M) polarity surface. This means that the nitrogen (N) polarity surface is etched at a much faster rate in a wet (using a liquid solution) or dry (using a plasma) etching process. Even when etching and CMP processes that have been researched and developed so far are used to treat the rough surface due to the above-described laser damage region formed during the LLO process, and the ID and IDB that are inevitably present inherently, there are technical difficulties in performing wafer bonding directly (without an interlayer) or indirectly (with the interlayer) by drastically improving the surface roughness of the group III nitride semiconductor layer C with the nitrogen (N) polarity surface, and thus a process for resolving such technical difficulties should be introduced.

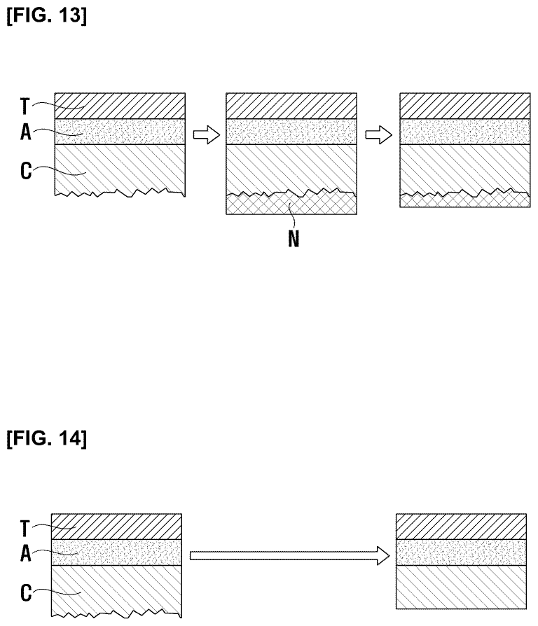

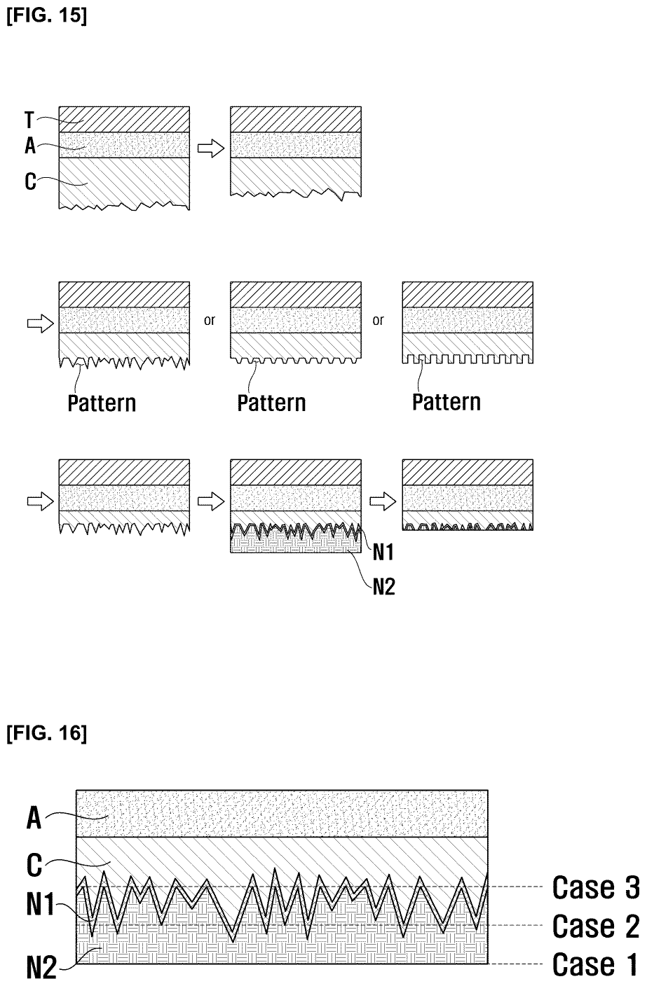

FIG. 13 shows a first case of the seventh operation in the method of manufacturing a semiconductor template according to the second or fourth embodiment of the present invention, FIG. 14 shows a second case of the seventh operation in the method of manufacturing a semiconductor template according to the second or fourth embodiment of the present invention, FIG. 15 show a third case of the seventh operation in the method of manufacturing a semiconductor template according to the second or fourth embodiment of the present invention, and FIG. 16 shows a third case of the seventh operation in the method of manufacturing a semiconductor template according to the first or third embodiment of the present invention, in which a degree of planarization is adjusted in three cases.

As shown in FIG. 13, the first case of the seventh operation S207 will now be described. In the first case, after the growth substrate G is separated in the sixth operation S206, a planarization layer N is formed as a thick film by depositing a high heat-resistant ceramic material such as silicon (Si), silicon oxide (SiO2), silicon nitride (SiNx), aluminum nitride (AlN), or aluminum oxide (Al2O3) on the group III nitride semiconductor layer C with the nitrogen polarity surface as a single layer or multiple layers through a PVD (sputtering, PLD, MBE, evaporator), CVD, or liquid coating process. Then, the planarization layer N deposited as the thick film is planarized to have a mirror-like surface through the CMP process. In this case, when the heat dissipation aspect is considered, aluminum nitride (AlN) with excellent heat dissipation properties is preferable, and when the ease and economy of the CMP process are considered, silicon (Si) and silicon oxide (SiO2) are preferable. In addition, a liquid coating process is known to be economical compared to PVD and CVD, and when using this process, silicon oxide (SiO2) is preferable (SOG). Thereafter, in the eighth operation S208, the first bonding layer B1 is formed on the planarized planarization layer N. Meanwhile, in the present invention, when bonding is possible with only the planarization layer N, direct bonding may be performed without the first bonding layer B1 or the second bonding layer B2.

Meanwhile, as shown in FIG. 14, a second case of the seventh operation S207 will now be described. In the second case, after the growth substrate G is separated in the sixth operation S206, the upper surface of the group III nitride semiconductor layer C is directly planarized to have a mirror-like surface through the CMP process. In this case, although there is an advantage in that the process is simple, it is necessary to separately optimize (slurry and conditions) the CMP process for the group III nitride semiconductor layer C with the nitrogen polarity (N-polarity) surface. Then, in the eighth operation S208, the first bonding layer B1 is formed on the planarized group III nitride semiconductor layer C.

Meanwhile, as shown in FIG. 15, a third case of the seventh operation S207 will now be described. In the third case, after the growth substrate G is separated in the sixth operation S206, the upper surface of the group III nitride semiconductor layer C is selectively (meaning that the process may be omitted as needed) dry-etched to remove a region in which many defects occur at an initial stage of growth.

Then, in the eighth operation S208, a surface area is expanded by etching the group III nitride semiconductor layer C so that regular or irregular patterns are formed on the upper surface of the group III nitride semiconductor layer C. In this case, the regular patterns may be formed by a general pattern/etching process, for example, such as photo lithography, and the formed patterns are not limited in size, interval, height, etc., but the larger the surface area, the more advantageous it is in terms of heat dissipation and bonding properties. In addition, the irregular patterns may be formed by, for example, surface-texturing the group III nitride semiconductor layer C with the nitrogen polarity surface with a basic solution containing an OH component according to the wet etching characteristics of the group III nitride semiconductor layer C with the nitrogen polarity (N-polarity) surface and then planarizing the peaked part of the hexagonal pyramid-shaped surface formed by surface texturing to have the flat plateau shape through the plasma dry etching as an optional subsequent process. Meanwhile, a cross section of the formed pattern may be a quadrangle, trapezoid, curved surface, etc., but is not limited thereto.

Then, an upper surface of the group III nitride semiconductor layer C with the expanded surface area may be selectively dry-etched again, which may be performed to make a depth of an unevenness deeper or secure the uniformity of a pattern height after texturing.

Then, after a single-layer or multilayered first planarization layer N1 is deposited or grown on the group III nitride semiconductor layer C on which the patterns have been etched along the patterns of the group III nitride semiconductor layer C, a single-layer or multilayered second planarization layer N2 is deposited or grown on the first planarization layer N1. For example, although the first planarization layer N1 may be aluminum nitride (AlN) for high heat dissipation and the second planarization layer N2 may be silicon oxide (SiO2) for easy planarization, and the first planarization layer N1 may be silicon oxide (SiO2) for increased bonding strength and the second planarization layer N2 may be aluminum nitride (AlN) for high heat dissipation, the present invention is not limited thereto and various combinations are possible as needed.

Then, a surface on which the first planarization layer N1 and the second planarization layer N2 are deposited or grown may be planarized through the CMP process, and a degree of planarization may be controlled according to the physical properties of the first planarization layer N1 or the second planarization layer N2. That is, as shown in FIG. 16, when the first planarization layer N1 is aluminum nitride (AlN) and the second planarization layer N2 is silicon oxide (SiO2), it is preferable that the second planarization layer N2 is mostly etched in terms of heat dissipation (case 3 of FIG. 16), and when the first planarization layer N1 is silicon oxide (SiO2) and the second planarization layer N2 is aluminum nitride (AlN), it is preferable that the second planarization layer N2 is hardly etched in terms of heat dissipation (case 1 of FIG. 16).

The eighth operation S208 is an operation of forming a first bonding layer B1 on the group III nitride semiconductor layer C. Here, the first bonding layer B1 may contain a metal such as aluminum (Al), tungsten (W), or molybdenum (Mo) or an alloy thereof, silicon oxide (SiOx), silicon nitride (SiNx), aluminum oxide (Al2O3), aluminum nitride (AlN), aluminum gallium nitride (AlGaN), gallium nitride (GaN), indium gallium nitride (InGaN), indium nitride (InN), amorphous or polycrystalline silicon (Si), zinc oxide (ZnO), C60 (fullerene), or furthermore, may additionally contain a flowable oxide (FOx) such as SOG or hydrogen silsesquioxane (HSQ) to improve surface roughness. In particular, it is preferable to use a CVD process such as an MOCVD or ALD process for aluminum nitride (AlN), aluminum gallium nitride (AlGaN), gallium nitride (GaN), indium gallium nitride (InGaN), and indium nitride (InN) materials.

The ninth operation S209 is an operation of forming the second bonding layer B2 on the support substrate S. Here, like the first bonding layer B1, the second bonding layer B2 may contain a metal such as aluminum (Al), tungsten (W), or molybdenum (Mo) or an alloy thereof, silicon oxide (SiOx), silicon nitride (SiNx), aluminum oxide (Al2O3), aluminum nitride (AlN), aluminum gallium nitride (AlGaN), gallium nitride (GaN), indium gallium nitride (InGaN), indium nitride (InN), amorphous or polycrystalline silicon (Si), zinc oxide (ZnO), C60 (fullerene), or furthermore, may additionally contain a flowable oxide (FOx) such as SOG or hydrogen silsesquioxane (HSQ) to improve surface roughness. In particular, it is preferable to use a CVD process such as an MOCVD or ALD process for aluminum nitride (AlN), aluminum gallium nitride (AlGaN), gallium nitride (GaN), indium gallium nitride (InGaN), and indium nitride (InN) materials.

Meanwhile, the first bonding layer B1 and the second bonding layer B2 may each include a bonding reinforcement layer R, a surface planarization layer F, and a bonding layer J.

FIG. 9 shows in detail the first bonding layer B1 and the second bonding layer B2 that are manufactured by the method of manufacturing a group III nitride semiconductor template according to the first and second embodiments of the present invention.

As shown in FIG. 9, the bonding reinforcement layer R is formed to reinforce bonding with the group III nitride semiconductor layer C (in the case of the first bonding layer B1) or the support substrate S (in the case of the second bonding layer B2), and the bonding reinforcement layer R may contain, for example, silicon oxide (SiOx), silicon nitride (SiNx), chromium (Cr), titanium (Ti), molybdenum (Mo), or HMDS.

The surface planarization layer F is formed to decrease the surface roughness of the group III nitride semiconductor layer C or the support substrate S, and the surface planarization layer F may contain, for example, silicon oxide (SiOx), silicon nitride (SiNx), aluminum oxide (Al2O3), aluminum nitride (AlN), or amorphous or polycrystalline silicon (Si) to improve surface roughness. Furthermore, the surface planarization layer F may additionally contain a flowable oxide (FOX) such as SOG and HSQ.

The bonding layer J is formed to bond the first bonding layer B1 and the second bonding layer B2, may be made of a permanent bonding material, may contain a metal such as aluminum (Al), tungsten (W), or molybdenum (Mo) or an alloy thereof, silicon oxide (SiOx), silicon nitride (SiNx), aluminum oxide (Al2O3), aluminum nitride (AlN), aluminum gallium nitride (AlGaN), gallium nitride (GaN), indium gallium nitride (InGaN), indium nitride (InN), amorphous or polycrystalline silicon (Si), zinc oxide (ZnO), C60 (fullerene), or furthermore, may additionally contain a flowable oxide (FOx) such as SOG or hydrogen silsesquioxane (HSQ) to improve surface roughness. In particular, it is preferable to use a CVD process such as an MOCVD or ALD process for aluminum nitride (AlN), aluminum gallium nitride (AlGaN), gallium nitride (GaN), indium gallium nitride (InGaN), and indium nitride (InN) materials.

Meanwhile, the bonding reinforcement layer R and the surface planarization layer F may be selectively introduced or omitted according to a process, and when the bonding reinforcement layer R and the surface planarization layer F are omitted according to the process, the bonding layer J may be directly deposited on the group III nitride semiconductor layer C (in the case of the first bonding layer B1) or the support substrate S (in the case of the second bonding layer B2).

The tenth operation S210 is an operation of forming the bonding layer B by bonding the first bonding layer B1 and the second bonding layer B2. That is, the tenth operation is an operation of turning over the growth substrate G on which the first bonding layer B1 has been formed (deposited) and the temporary substrate T and pressing and bonding the growth substrate G to the support substrate S on which the second bonding layer B2 has been formed at a temperature of lower than 300° C.

Normally, to minimize wafer bowing after bonding, it is optimal to select the material of the support substrate S so that a difference in CTE with the growth substrate G may be less than 2 ppm, but the support substrate S such as Si, SiC, SiNx, AlN, and GaN, which have high heat dissipation performance, has a difference in CTE of 2 ppm or more from the sapphire growth substrate G, realistically making it difficult to bond the wafer at a high temperature. In this case, it is possible to minimize stress by setting a bonding process temperature to about room temperature and performing the process, thereby preventing wafer bowing.

The eleventh operation S211 is an operation of separating the temporary substrate T from the adhesive layer A using an LLO technique.

The twelfth operation S212 is an operation of separating the adhesive layer A from the nitride semiconductor layer C having the group III metal polarity (M-polarity) surface. Then, the contaminated group III metal (M) polarity surface residue may be removed.

In particular, the twelfth operation S212 is an operation of reinforcing the weak bonding layer B formed between the first bonding layer B1 and the second bonding layer B2 by annealing the group III nitride semiconductor layer C from which the temporary substrate T has been separated at a high temperature of 700° C. or higher before the thirteenth operation S213 of growing the element active layer U structure.

The thirteenth operation S213 is an operation of growing the element active layer U on the nitride semiconductor layer C having the group III metal (M) polarity surface. That is, through the previous operations, a semiconductor element active layer U structure containing a desired compound may be finally grown on the upper surface of the group III nitride semiconductor layer C formed on the high heat dissipation support substrate S. For example, in the case of the GaN material-based power semiconductor structure, the element active layer U may be typically formed by stacking four regions: 1) a GaN buffer layer (horizontal and vertical transistors), 2) a GaN channel layer (horizontal transistor) or a drift layer (vertical transistor), 3) an AlGaN barrier layer (horizontal transistor) or a p-type nitride semiconductor layer (vertical transistor), and 4) a capping passivation layer (horizontal transistor), a p-type nitride semiconductor layer (horizontal transistor), or a capping passivation layer (vertical transistor).

According to the method S200 of manufacturing a group III nitride semiconductor template according to the second embodiment of the present invention, which includes the first operation S201, the second operation S202, the third operation S203, the fourth operation S204, the fifth operation S205, the sixth operation S206, the seventh operation S207, the eighth operation S208, the ninth operation S209, the tenth operation S210, the eleventh operation S211, the twelfth operation S212, and the thirteenth operation S213, and the group III nitride semiconductor template manufactured using the same, the high heat dissipation support substrate S having a CTE that is the same as or similar to that of the group III nitride semiconductor layer C and the group III nitride single crystalline growth layer for the high-quality group III nitride thin film material and the power semiconductor device structure growth using the same may be bonded through a high heat-resistant bonding layer, thereby enabling the formation of a high-quality group III nitride semiconductor layer at a high temperature of 700° C. or higher. That is, since the group III nitride thin film material and the power semiconductor device structure using the same and the support substrate can have the same or similar lattice constant and CTE, it is possible to minimize structural stress and thermo-mechanical induced stress occurring during growth.

In addition, according to the present invention, since the pattern P may be etched to a preset depth on the group III nitride semiconductor layer C or the bonding layer B, it is advantageous for the wafer bonding process. That is, in the case of direct wafer bonding, it is quite sensitive to the surface roughness of the surface on which the wafer is bonded and wafer bowing, but according to the patterning of the present invention, there is an advantage in that the strict wafer surface roughness and bowing issue can be considerably alleviated. In addition, according to the patterning of the present invention, since gas generated inside the bonding layer B during the wafer bonding process can be easily discharged, the bonding strength of the bonding layer B can be reinforced in a void-free manner, and structural stress and thermo-mechanical induced stress can also be more effectively buffered.

In addition, according to the present invention, since the high heat dissipation support substrate S is made of a polycrystalline ceramic, there is an advantage in that the high heat dissipation support substrate is better than a single crystalline ceramic in terms of cost competitiveness.

In addition, according to the present invention, the polarity of the surface of the semiconductor layer C initially grown on the growth substrate G and the polarity of the surface of the semiconductor layer C finally formed on the support substrate S may be the same. To successfully execute this, a process for converting the rough surface due to the above-described laser damage region formed during the process and the ID and IDB that are inherently present, etc., into a mirror-like surface should be introduced.

A method S300 of manufacturing a group III nitride semiconductor template according to the third embodiment of the present invention will now be described in detail with reference to the accompanying drawings.

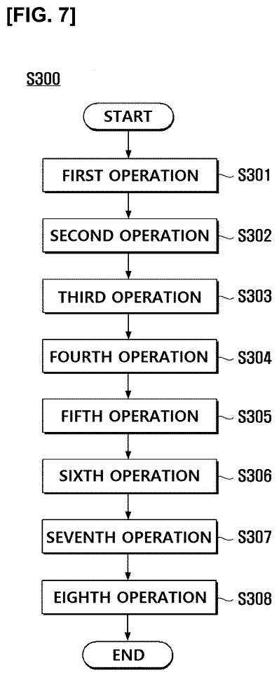

FIG. 1 shows a semiconductor template manufactured by a method of manufacturing a group III nitride semiconductor template according to first to fourth embodiments of the present invention, FIG. 2 shows that an element active layer is grown on the semiconductor template manufactured by the method of manufacturing a group III nitride semiconductor template according to the first to fourth embodiments of the present invention, and FIG. 7 is a flowchart of the method of manufacturing a group III nitride semiconductor template according to the third embodiment of the present invention.

As shown in FIGS. 1, 2, and 7, the method S300 of manufacturing a group III nitride semiconductor template according to the third embodiment of the present invention relates to a method of manufacturing a semiconductor template in which the polarities of the surface of the group III nitride semiconductor layer C initially grown on the growth substrate G and the surface of the group III nitride semiconductor layer C finally formed on the support substrate S are different (i.e., opposite), and particularly, to a case where the support substrate S is a polycrystalline aluminum nitride (AlN) ceramic substrate.

The method S300 of manufacturing a group III nitride semiconductor template according to the third embodiment of the present invention includes a first operation S301, a second operation S302, a third operation S303, a fourth operation S304, a fifth operation S305, a sixth operation S306, a seventh operation S307, and an eighth operation S308.

The first operation S301 is an operation of preparing the growth substrate G and the support substrate S.

The growth substrate G is an optically transparent substrate through which a laser (single wavelength light) beam is 100% transmitted (theoretically) without absorption after the group III nitride semiconductor layer C is grown, and in the present disclosure, is limited to a single crystalline sapphire material-based (Al2O3, ScAlMgO4) substrate containing aluminum oxide (Al2O3).

The support substrate S is a substrate that supports the semiconductor layer C and the element active layer U after undergoing each operation of the method S300 of manufacturing a group III nitride semiconductor template according to the third embodiment of the present invention, and the support substrate S may be a polycrystalline aluminum nitride (AlN) ceramic substrate. The polycrystalline AlN ceramic support substrate S is intended to overcome the difference in CTE between the silicon (Si) single crystalline wafer (CTE: 2.8 ppm) and the GaN (CTE: 5.6 ppm) material, and the polycrystalline AlN ceramic has a CTE of 4.5 ppm, which is similar to the CTE of GaN.

The second operation S302 is an operation of growing the group III nitride semiconductor layer C on the growth substrate G as a single layer or multiple layers.

Here, it is preferable that the group III nitride semiconductor layer C basically has dopant-free electrical insulation properties, but in some cases, has electrical conduction properties including a dopant as a means for minimizing crystal defects and serves as a seed for growing the group III nitride thin film material and the power semiconductor device structure using the same.

Here, since a surface of the group III nitride semiconductor layer C formed on the growth substrate G and a surface of the group III nitride semiconductor layer C transferred onto the support substrate S are inverted, it is preferable to form a microstructure by treating a surface of the growth substrate G so that a predetermined surface of the semiconductor layer C may be preferably formed. For example, in the case of a gallium nitride (GaN) semiconductor layer C, a gallium polarity (Ga-polarity) or nitrogen polarity (N-polarity) surface may be selectively controlled according to the surface treatment and growth conditions of the growth substrate G. Typically, when the group III nitride semiconductor layer C is grown on a sapphire growth substrate wafer in an MOCVD chamber, while the group III nitride semiconductor layer C has a surface with a metal (M: Ga, Al, In) polarity with 3 valence electrons, an interface in direct contact with the sapphire growth substrate has a nitrogen polarity with 5 valence electrons.

The third operation S303 is an operation of forming the first bonding layer B1 on the group III nitride semiconductor layer C. Here, the first bonding layer B1 may contain a metal such as aluminum (Al), tungsten (W), or molybdenum (Mo) or an alloy thereof, silicon oxide (SiOx), silicon nitride (SiNx), aluminum oxide (Al2O3), aluminum nitride (AlN), aluminum gallium nitride (AlGaN), gallium nitride (GaN), indium gallium nitride (InGaN), indium nitride (InN), amorphous or polycrystalline silicon (Si), zinc oxide (ZnO), C60 (fullerene), or furthermore, may additionally contain a flowable oxide (FOX) such as SOG or hydrogen silsesquioxane (HSQ) to improve surface roughness. In particular, it is preferable to use a CVD process such as an MOCVD or ALD process for aluminum nitride (AlN), aluminum gallium nitride (AlGaN), gallium nitride (GaN), indium gallium nitride (InGaN), and indium nitride (InN) materials.

The fourth operation S304 is an operation of forming the second bonding layer B2 on the polycrystalline aluminum nitride (AlN) ceramic support substrate S. Here, the second bonding layer B2 may contain a metal such as aluminum (Al), tungsten (W), or molybdenum (Mo) or an alloy thereof, silicon oxide (SiOx), silicon nitride (SiNx), aluminum oxide (Al2O3), aluminum nitride (AlN), aluminum gallium nitride (AlGaN), gallium nitride (GaN), indium gallium nitride (InGaN), indium nitride (InN), amorphous or polycrystalline silicon (Si), zinc oxide (ZnO), C60 (fullerene), or furthermore, may additionally contain a flowable oxide (FOX) such as SOG or hydrogen silsesquioxane (HSQ) to improve surface roughness. In particular, it is preferable to use a CVD process such as an MOCVD or ALD process for aluminum nitride (AlN), aluminum gallium nitride (AlGaN), gallium nitride (GaN), indium gallium nitride (InGaN), and indium nitride (InN) materials.

Meanwhile, the first bonding layer B1 and the second bonding layer B2 may each include a bonding reinforcement layer R, a surface planarization layer F, and a bonding layer J.

FIG. 9 shows in detail the first bonding layer B1 and the second bonding layer B2 that are manufactured by the method of manufacturing a group III nitride semiconductor template according to the first to fourth embodiments of the present invention.

As shown in FIG. 9, the bonding reinforcement layer R is formed to reinforce bonding with the group III nitride semiconductor layer C (in the case of the first bonding layer B1) or the support substrate S (in the case of the second bonding layer B2), and the bonding reinforcement layer R may contain, for example, silicon oxide (SiOx), silicon nitride (SiNx), chromium (Cr), titanium (Ti), molybdenum (Mo), or HMDS.

The surface planarization layer F is formed to decrease the surface roughness of the group III nitride semiconductor layer C or the support substrate S, and the surface planarization layer F may contain, for example, silicon oxide (SiOx), silicon nitride (SiNx), aluminum oxide (Al2O3), aluminum nitride (AlN), or amorphous or polycrystalline silicon (Si) to improve surface roughness. Furthermore, the surface planarization layer F may additionally contain a flowable oxide (FOx) such as SOG and HSQ.

The bonding layer J is formed to bond the first bonding layer B1 and the second bonding layer B2, may be made of a permanent bonding material, may contain a metal such as aluminum (Al), tungsten (W), or molybdenum (Mo) or an alloy thereof, silicon oxide (SiOx), silicon nitride (SiNx), aluminum oxide (Al2O3), aluminum nitride (AlN), aluminum gallium nitride (AlGaN), gallium nitride (GaN), indium gallium nitride (InGaN), indium nitride (InN), amorphous or polycrystalline silicon (Si), zinc oxide (ZnO), C60 (fullerene), or furthermore, may additionally contain a flowable oxide (FOx) such as SOG or hydrogen silsesquioxane (HSQ) to improve surface roughness. In particular, it is preferable to use a CVD process such as an MOCVD or ALD process for aluminum nitride (AlN), aluminum gallium nitride (AlGaN), gallium nitride (GaN), indium gallium nitride (InGaN), and indium nitride (InN) materials.

Meanwhile, the bonding reinforcement layer R and the surface planarization layer F may be selectively introduced or omitted according to a process, and when the bonding reinforcement layer R and the surface planarization layer F are omitted according to the process, the bonding layer J may be directly deposited on the group III nitride semiconductor layer C (in the case of the first bonding layer B1) or the support substrate S (in the case of the second bonding layer B2).

The fifth operation S305 is an operation of forming the bonding layer B by bonding the first bonding layer B1 and the second bonding layer B2. That is, the fifth operation S305 is an operation of turning over the growth substrate G on which the first bonding layer B1 has been formed (deposited) and pressing and bonding the growth substrate G to the polycrystalline aluminum nitride (AlN) ceramic support substrate S on which the second bonding layer B2 has been formed at a temperature of lower than 300° C.

Normally, to minimize wafer bowing after bonding, it is optimal to select the material of the support substrate S so that a difference in CTE with the growth substrate G may be less than 2 ppm, but the polycrystalline aluminum nitride (AlN) ceramic support substrate S such as Si, SiC, SiNx, AlN, and GaN, which have high heat dissipation performance, has a difference in CTE of 2 ppm or more from the sapphire growth substrate G, realistically making it difficult to bond the wafer at a high temperature. In this case, it is possible to minimize stress by setting a bonding process temperature to about room temperature and performing the process, thereby preventing wafer bowing.

The sixth operation S306 is an operation of separating the optically transparent growth substrate G from the group III nitride semiconductor layer C using an LLO technique. Here, the LLO technique is a technique of separating an epitaxy-grown layer from the growth substrate G by irradiating a back surface of the transparent growth substrate G with an ultraviolet (UV) laser beam having a uniform optical output and beam profile and a single wavelength. Then, a damaged region, contaminated surface residue, and low-quality single crystalline thin film region due to the separation of the growth substrate G may be removed as completely as possible.

The seventh operation S307 is an operation of reinforcing the weak bonding layer B formed between the first bonding layer B1 and the second bonding layer B2 by forming a polarity transform layer W for transforming a surface polarity of the group III nitride semiconductor layer C from a nitrogen polarity (N-polarity) to a group III metal polarity (M(Ga, Al, In)-polarity) before growing the group III nitride semiconductor element active layer U on the group III nitride semiconductor layer C and annealing the group III nitride semiconductor layer C from which the growth substrate G has been separated at a high temperature of 700° C. or higher. In some cases, the order of the process of forming the polarity transform layer W for transforming the surface polarity and the high-temperature annealing process for reinforcing the bonding layer B may be changed.

As described above, the widely commercialized transparent growth substrate G is sapphire, and when the group III nitride semiconductor layer C is grown on the sapphire growth substrate G in an MOCVD chamber, while the group III nitride semiconductor layer C has a surface with a metal (M: Ga, Al, In) polarity with 3 valence electrons, an interface in direct contact with the sapphire growth substrate has a nitrogen polarity with 5 valence electrons. Therefore, the surface polarity of the group III nitride semiconductor layer C finally formed on the support substrate S has a nitrogen polarity (N-polarity) surface unlike the metal polarity (M-polarity) surface grown on the sapphire growth substrate G. However, there is a serious technical difficulty in securing high quality when growing the stacked structure of the group III nitride semiconductor element active layer U on such a nitrogen polarity surface, and furthermore, even when growth is possible, there is a disadvantage that a growth rate is very low. That is, to implement the high-quality group III nitride semiconductor element active layer U, a process of transforming the surface polarity of the group III nitride semiconductor layer C formed on the support substrate S so that the surface of the group III nitride semiconductor layer C necessarily has the group III metal polarity (M (Al, Ga, In)-polarity) rather than the nitrogen polarity should be introduced.

To this end, the seventh operation S307 includes, after separating the growth substrate G and before loading the Si single crystalline wafer in the MOCVD chamber, depositing or growing the polarity transform layer W that promotes the group III metal (M) polarity such as aluminum (Al), aluminum nitride (AlN), or aluminum nitride oxide (AlNO) on the group III nitride semiconductor layer C with the nitrogen polarity surface through a PVD (sputtering, PLD, MBE, evaporator) process. Thereafter, in the eighth operation S308 to be described below, the element active layer U is grown on an upper surface of the polarity transform layer W.

FIG. 10 shows a first case of the seventh operation in the method of manufacturing a semiconductor template according to the first or third embodiment of the present invention, FIG. 11 shows a second case of the seventh operation in the method of manufacturing a semiconductor template according to the first or third embodiment of the present invention, and FIG. 12 show a third case of the seventh operation in the method of manufacturing a semiconductor template according to the first or third embodiment of the present invention.

Meanwhile, as shown in FIG. 10, the first case of the seventh operation S307 will now be described. In the first case, after the growth substrate G is separated in the sixth operation S306, an upper surface of the group III nitride semiconductor layer C is selectively (meaning that the process may be omitted as needed) dry-etched, and then the upper surface of the nitride semiconductor layer C is selectively planarized through a CMP process. Then, the polarity transform layer W that promotes the group III metal polarity (M-polarity) such as aluminum (Al), aluminum nitride (AlN), aluminum nitride oxide (AlNO), gallium (Ga), gallium nitride (GaN), gallium nitride oxide (GaNO), indium (In), indium nitride (InN), and indium nitride oxide (InNO) on the group III nitride semiconductor layer C with the nitrogen polarity surface is deposited or grown through the PVD (sputtering, PLD, MBE, evaporator) process, and in this case, various patterns may be formed by etching the deposited or grown polarity transform layer W, the etched pattern may be regular or irregular, and a shape, size, spacing, and height are not limited. Then, in the eighth operation S308 to be described below, the element active layer U may be grown on an upper surface of the polarity transform layer W, and when the pattern is formed by etching the polarity transform layer W, multiple voids may be formed at an interface between the polarity transform layer W and the element active layer U in contact with the same. The voids have an effect of relieving the stress of the re-grown group III nitride semiconductor layer C.

Meanwhile, as shown in FIG. 11, a second case of the seventh operation S307 will now be described. In the second case, after the growth substrate G is separated in the sixth operation S306, the upper surface of the group III nitride semiconductor layer C is selectively (meaning that the process may be omitted as needed) dry-etched, and then the upper surface of the nitride semiconductor layer C is selectively planarized through a CMP process. Then, various patterns may be formed by etching the upper surface of the group III nitride semiconductor layer C, and the etched pattern may be regular or irregular, and the shape, size, spacing, height, etc. are not limited. Then, the polarity transform layer W that promotes the group III metal polarity (M-polarity) such as aluminum (Al), aluminum nitride (AlN), aluminum nitride oxide (AlNO), gallium (Ga), gallium nitride (GaN), gallium nitride oxide (GaNO), indium (In), indium nitride (InN), and indium nitride oxide (InNO) on the group III nitride semiconductor layer C on which the patterns of the nitrogen polarity surface have been etched is deposited or grown along the patterns of the group III nitride semiconductor layer C through a PVD (sputtering, PLD, MBE, evaporator) process. Then, in the eighth operation S308 to be described below, the element active layer U may be grown on the upper surface of the polarity transform layer W, and as needed, the element active layer U may be grown to fill the etched pattern to prevent voids from being formed therein, or the element active layer U may be grown so that the etched patterns are not filled to form voids therein. The voids have an effect of relieving the stress of the re-grown group III nitride semiconductor layer C.

Meanwhile, as shown in FIG. 12, a third case of the seventh operation S307 will now be described. In the third case, after the growth substrate G is separated in the sixth operation S306, the upper surface of the group III nitride semiconductor layer C is selectively (meaning that the process may be omitted as needed) dry-etched. Then, various patterns may be formed by etching the upper surface of the group III nitride semiconductor layer C, and the etched pattern may be regular or irregular, and the shape, size, spacing, height, etc. are not limited. Then, after the upper surface of the group III nitride semiconductor layer C on which the patterns have been etched is selectively dry-etched, each end portion of the pattern is planarized (peak planarization) through a photo-resistor (PR) mask or CMP process. For example, after forming patterns by surface-texturing the group III nitride semiconductor layer C with the nitrogen polar surface with a basic solution containing an OH component, a peaked part of a hexagonal pyramid-shaped surface formed by surface texturing may be planarized to have a flat plateau shape through a plasma dry process as a subsequent process. Then, the polarity transform layer W that promotes the group III metal polarity (M-polarity) such as aluminum (Al), aluminum nitride (AlN), aluminum nitride oxide (AlNO), gallium (Ga), gallium nitride (GaN), gallium nitride oxide (GaNO), indium (In), indium nitride (InN), and indium nitride oxide (InNO) on the group III nitride semiconductor layer C on which the patterns of the nitrogen polarity surface have been etched is deposited or grown along the patterns of the group III nitride semiconductor layer C through a PVD (sputtering, PLD, MBE, evaporator) process. Then, in the eighth operation S308 to be described below, the element active layer U may be grown on the upper surface of the polarity transform layer W, and as needed, the element active layer U may be grown to fill the etched pattern to prevent voids from being formed therein, or the element active layer U may be grown so that the etched patterns are not filled to form voids therein. The voids have an effect of relieving the stress of the re-grown group III nitride semiconductor layer C.

The eighth operation S308 is an operation of growing the group III nitride semiconductor element active layer U on the group III nitride semiconductor layer C. That is, through the previous operations, a semiconductor element active layer U structure containing a desired compound may be finally grown on the upper surface of the group III nitride semiconductor layer C formed on the high heat dissipation support substrate S. For example, in the case of the GaN material-based power semiconductor structure, the element active layer U may be typically formed by stacking four regions: 1) a GaN buffer layer (horizontal and vertical transistors), 2) a GaN channel layer (horizontal transistor) or a drift layer (vertical transistor), 3) an AlGaN barrier layer (horizontal transistor) or a p-type nitride semiconductor layer (vertical transistor), and 4) a capping passivation layer (horizontal transistor), a p-type nitride semiconductor layer (horizontal transistor), or a capping passivation layer (vertical transistor).

According to the method S300 of manufacturing a group III nitride semiconductor template according to the third embodiment of the present invention, which includes the first operation S301, the second operation S302, the third operation S303, the fourth operation S304, the fifth operation S305, the sixth operation S306, the seventh operation S307, and the eighth operation S308, and the group III nitride semiconductor template manufactured using the same, the high heat dissipation support substrate S having a CTE that is the same as or similar to that of the group III nitride semiconductor layer C and the group III nitride single crystalline growth layer for the high-quality group III nitride thin film material and the power semiconductor device structure growth using the same may be bonded through a high heat-resistant bonding layer, thereby enabling the formation of a high-quality group III nitride semiconductor layer at a high temperature of 700° C. or higher. That is, since the group III nitride thin film material and the power semiconductor device structure using the same and the support substrate can have the same or similar lattice constant and CTE, it is possible to minimize structural stress and thermo-mechanical induced stress occurring during growth.

In addition, according to the present invention, since the pattern P may be formed to a preset depth by etching the group III nitride semiconductor layer C or the bonding layer B, it is advantageous for the wafer bonding process. That is, in the case of direct wafer bonding, it is quite sensitive to the surface roughness of the surface on which the wafer is bonded and wafer bowing, but according to the patterning of the present invention, there is an advantage in that the strict wafer surface roughness and bowing issue can be considerably alleviated. In addition, according to the patterning of the present invention, since gas generated inside the bonding layer B during the wafer bonding process can be easily discharged, the bonding strength of the bonding layer B can be reinforced in a void-free manner, and structural stress and thermo-mechanical induced stress can also be more effectively buffered.

In addition, according to the present invention, since the high heat dissipation support substrate S is made of a polycrystalline ceramic, there is an advantage in that the high heat dissipation support substrate is better than a single crystalline ceramic in terms of cost competitiveness.

In addition, according to the present invention, although the polarity of the surface of the group III nitride semiconductor layer C initially grown on the growth substrate G and the polarity of the surface of the semiconductor layer C finally formed on the support substrate S are different (i.e., opposite), before growing the group III nitride semiconductor element active layer U, a material layer that promotes group III metal polarity (M-polarity) may be introduced to grow the high-quality group III nitride semiconductor element active layer U.

A method S400 of manufacturing a group III nitride semiconductor template according to the fourth embodiment of the present invention will now be described in detail with reference to the accompanying drawings.

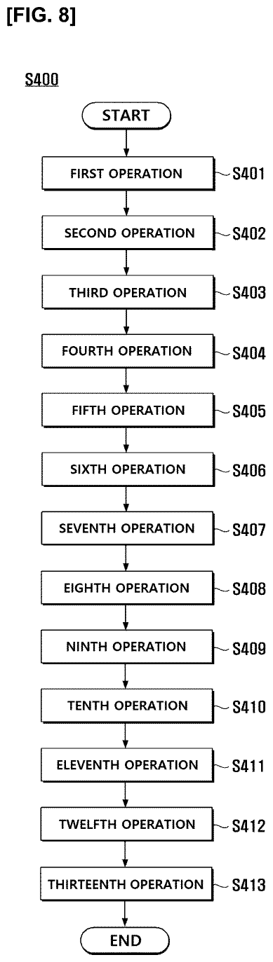

FIG. 1 shows a semiconductor template manufactured by a method of manufacturing a group III nitride semiconductor template according to first to fourth embodiments of the present invention, FIG. 2 shows that an element active layer is grown on the semiconductor template manufactured by the method of manufacturing a group III nitride semiconductor template according to the first to fourth embodiments of the present invention, and FIG. 8 is a flowchart of the method of manufacturing a group III nitride semiconductor template according to the fourth embodiment of the present invention.

As shown in FIGS. 1, 2, and 8, the method S400 of manufacturing a group III nitride semiconductor template according to the fourth embodiment of the present invention relates to a method of manufacturing a semiconductor template in which the polarities of the surface of the group III nitride semiconductor layer C initially grown on the growth substrate G and the surface of the group III nitride semiconductor layer C finally formed on the support substrate S are the same, and particularly, to a case where the support substrate S is a polycrystalline aluminum nitride (AlN) ceramic substrate.

The method S400 of manufacturing a group III nitride semiconductor template according to the fourth embodiment of the present invention includes a first operation S401, a second operation S402, a third operation S403, a fourth operation S404, a fifth operation S405, a sixth operation S406, a seventh operation S407, an eighth operation S408, a ninth operation S409, a tenth operation S410, an eleventh operation S411, a twelfth operation S412, and a thirteenth operation S413.

The first operation S401 is an operation of preparing the growth substrate G, the temporary substrate T, and the support substrate S.

The growth substrate G is an optically transparent substrate through which a laser (single wavelength light) beam is 100% transmitted (theoretically) without absorption after the group III nitride semiconductor layer C is grown, and in the present disclosure, is limited to a single crystalline sapphire material-based (Al2O3, ScAlMgO4) substrate containing aluminum oxide (Al2O3).

The support substrate S is a substrate that supports the semiconductor layer C and the element active layer U after undergoing each operation of the method S400 of manufacturing a group III nitride semiconductor template according to the fourth embodiment of the present invention, and the support substrate S may be a polycrystalline aluminum nitride (AlN) ceramic substrate. The polycrystalline AlN ceramic support substrate S is intended to overcome the difference in CTE between the silicon (Si) single crystalline wafer (CTE: 2.8 ppm) and the GaN (CTE: 5.6 ppm) material, and the polycrystalline AlN ceramic has a CTE of 4.5 ppm, which is similar to the CTE of GaN.

The temporary substrate T is made of a material that has a CTE that is the same as or similar to that of the growth substrate G and at the same time, optically transparent, and it is preferable that a difference in CTE does not exceed a maximum of 2 ppm. The most preferable temporary substrate T material that satisfies the above may include sapphire used as the group III nitride semiconductor growth substrate G or glass whose CTE has been adjusted to have a difference of 2 ppm or less from the growth substrate G.

The second operation S402 is an operation of growing the group III nitride semiconductor layer C on the growth substrate G as a single layer or multiple layers.

Here, it is preferable that the group III nitride semiconductor layer C basically has dopant-free electrical insulation properties, but in some cases, has electrical conduction properties including a dopant as a means for minimizing crystal defects and serves as a seed for growing the group III nitride thin film material and the power semiconductor device structure using the same.

Here, since a surface of the group III nitride semiconductor layer C formed on the growth substrate G and a surface of the group III nitride semiconductor layer C transferred onto the support substrate S are inverted, it is preferable to form a microstructure by treating a surface of the growth substrate G so that a predetermined surface of the semiconductor layer C may be preferably formed. For example, in the case of a gallium nitride (GaN) semiconductor layer C, a gallium polarity (Ga-polarity) or nitrogen polarity (N-polarity) surface may be selectively controlled according to the surface treatment and growth conditions of the growth substrate G. Typically, when the group III nitride semiconductor layer C is grown on a sapphire growth substrate wafer in an MOCVD chamber, while the group III nitride semiconductor layer C has a surface with a metal (M: Ga, Al, In) polarity with 3 valence electrons, an interface in direct contact with the sapphire growth substrate has a nitrogen polarity with 5 valence electrons.

The third operation S403 is an operation of forming a first adhesive layer Al on the group III nitride semiconductor layer C.

Here, before forming the first adhesive layer Al on the group III nitride semiconductor layer C, it is preferable to deposit or coat a protective layer to prevent the semiconductor layer C from being damaged during a subsequent process. A material for this purpose may include, for example, oxides including SiO2, nitrides including SiNx, etc.

The fourth operation S404 is an operation of forming a second adhesive layer A2 on the temporary substrate T.

Here, the optically transparent temporary substrate T is a substrate that is ultimately easily separated by an LLO technique in the subsequent process, and it is essential to deposit an LLO sacrificial layer on the temporary substrate T before forming the second adhesive layer A2. As needed, a bonding reinforcement layer may be separately provided before the LLO sacrificial layer is deposited so that an LLO sacrificial layer material may be strongly bonded to an upper portion of the temporary substrate T. In this case, the bonding reinforcement layer may preferentially contain, for example, an oxide including SiO2, a nitride including SiNx, etc., which are optically transparent materials when a laser beam is radiated. In addition, the above-described LLO sacrificial layer material may include an oxide, a nitride, etc., which may be deposited by a PVD technique such as a sputtering, pulsed laser deposition (PLD), or an evaporator.

Here, the first adhesive layer A1 and the second adhesive layer A2 may include a flowable oxide (FOx) such as benzocyclobuene (BCB), a SU-8 polymer, SOG or HSQ for improving surface roughness, etc.

The fifth operation S405 is an operation of forming the adhesive layer A by attaching the first adhesive layer A1 to the second adhesive layer A2. That is, the fifth operation S405 is an operation of turning over the temporary substrate T on which the second adhesive layer A2 has been formed and pressing and bonding the temporary substrate T to the growth substrate G on which the first adhesive layer A1 has been formed at a temperature of lower than 300° C.

The sixth operation S406 is an operation of separating the optically transparent growth substrate G from the group III nitride semiconductor layer C using an LLO technique. Here, the LLO technique is a technique of separating an epitaxy-grown layer from the growth substrate G by irradiating a back surface of the transparent growth substrate G with an ultraviolet (UV) laser beam having a uniform optical output and beam profile and a single wavelength. Then, a damaged region, contaminated surface residue, and low-quality single crystalline thin film region due to the separation of the growth substrate G may be removed as completely as possible.

The seventh operation S407 is an operation of converting a rough surface due to a laser damage area caused by the above-described LLO process, an inversion domain (ID) and inversion domain boundary (IDB) that are inherently present, etc., into a mirror-like surface before forming the first bonding layer B1 on the group III nitride semiconductor layer C.

The nitrogen polarity (N-polarity) surface from which the growth substrate G has been separated by the LLO technique has not only laser damage parts due to the instability of the laser beam and contamination of the back surface of the growth substrate G, but also has surface regions with inherent group III metal polarity (M-polarity) sporadically distributed in a region adjacent to the growth substrate G even when there is a difference in amount when the group III nitride semiconductor layer C is initially grown on the growth substrate G. A dominant polarity in the above-described region adjacent to the growth substrate G is basically nitrogen (N), but the sporadically distributed group III metal (M) polarity region is referred to as the inversion domain (ID), and at the same time, a boundary between a nitrogen (N) polarity plane and a group III metal polarity region (ID) plane in contact therewith in a thickness (growth) direction of the group III nitride semiconductor layer C is referred to as the inversion domain boundary (IDB). In particular, the nitrogen (N) polarity surface has a characteristic that it is chemically very unstable compared to the group III metal (M) polarity surface. This means that the nitrogen (N) polarity surface is etched at a much faster rate in a wet (using a liquid solution) or dry (using a plasma) etching process. Even when etching and CMP processes that have been researched and developed so far are used to treat the rough surface due to the above-described laser damage region formed during the LLO process, the ID and IDB that are inevitably present inherently, there are technical difficulties in performing wafer bonding directly (without an interlayer) or indirectly (with the interlayer) by drastically improving the surface roughness of the group III nitride semiconductor layer C with the nitrogen (N) polarity surface, and thus a process for resolving such technical difficulties should be introduced.

FIG. 13 shows a first case of the seventh operation in the method of manufacturing a semiconductor template according to the second or fourth embodiment of the present invention, FIG. 14 shows a second case of the seventh operation in the method of manufacturing a semiconductor template according to the second or fourth embodiment of the present invention, FIG. 15 show a third case of the seventh operation in the method of manufacturing a semiconductor template according to the second or fourth embodiment of the present invention, and FIG. 16 shows a third case of the seventh operation in the method of manufacturing a semiconductor template according to the first or third embodiment of the present invention, in which a degree of planarization is adjusted in three cases.

As shown in FIG. 13, the first case of the seventh operation S407 will now be described. In the first case, after the growth substrate G is separated in the sixth operation S406, a planarization layer N is formed as a thick film by depositing a high heat-resistant ceramic material such as silicon (Si), silicon oxide (SiO2), silicon nitride (SiNx), aluminum nitride (AlN), or aluminum oxide (Al2O3) on the group III nitride semiconductor layer C with the nitrogen polarity surface as a single layer or multiple layers through a PVD (sputtering, PLD, MBE, evaporator), CVD, or liquid coating process. Then, the planarization layer N deposited as the thick film is planarized to have a mirror-like surface through a CMP process. In this case, when the heat dissipation aspect is considered, aluminum nitride (AlN) with excellent heat dissipation properties is preferable, and when the ease and economy of the CMP process are considered, silicon (Si) and silicon oxide (SiO2) are preferable. In addition, a liquid coating process is known to be economical compared to PVD and CVD, and when using this process, silicon oxide (SiO2) is preferable (SOG). Thereafter, in the eighth operation S408, the first bonding layer B1 is formed on the planarized planarization layer N. Meanwhile, in the present invention, when bonding is possible with only the planarization layer N, direct bonding may be performed without the first bonding layer B1 or the second bonding layer B2.

Meanwhile, as shown in FIG. 14, a second case of the seventh operation S407 will now be described. In the second case, after the growth substrate G is separated in the sixth operation S406, the upper surface of the group III nitride semiconductor layer C is directly planarized to have a mirror-like surface through the CMP process. In this case, although there is an advantage in that the process is simple, it is necessary to separately optimize (slurry and conditions) the CMP process for the group III nitride semiconductor layer C with the nitrogen polarity (N-polarity) surface. Then, in the eighth operation S408, the first bonding layer B1 is formed on the planarized group III nitride semiconductor layer C.

Meanwhile, as shown in FIG. 15, a third case of the seventh operation S407 will now be described. In the third case, after the growth substrate G is separated in the sixth operation S406, the upper surface of the group III nitride semiconductor layer C is selectively (meaning that the process may be omitted as needed) dry-etched to remove a region in which many defects occur at an initial stage of growth.

Then, in the eighth operation S208, a surface area is expanded by etching the group III nitride semiconductor layer C so that regular or irregular patterns are formed on the upper surface of the group III nitride semiconductor layer C. In this case, the regular patterns may be formed by a general pattern/etching process, for example, such as photo lithography, and the formed patterns are not limited in size, interval, height, etc., but the larger the surface area, the more advantageous it is in terms of heat dissipation and bonding properties. In addition, the irregular patterns may be formed by, for example, surface-texturing the group III nitride semiconductor layer C with the nitrogen polarity surface with a basic solution containing an OH component according to the wet etching characteristics of the group III nitride semiconductor layer C with the nitrogen polarity (N-polarity) surface and then planarizing the peaked part of the hexagonal pyramid-shaped surface formed by surface texturing to have the flat plateau shape through the plasma dry etching as an optional subsequent process. Meanwhile, a cross section of the formed pattern may be a quadrangle, trapezoid, curved surface, etc., but is not limited thereto.

Then, an upper surface of the group III nitride semiconductor layer C with the expanded surface area may be selectively dry-etched again, which may be performed to make a depth of an unevenness deeper or secure the uniformity of a pattern height after texturing.

Then, after a single-layer or multilayered first planarization layer N1 is deposited or grown on the group III nitride semiconductor layer C on which the patterns have been etched along the patterns of the group III nitride semiconductor layer C, a single-layer or multilayered second planarization layer N2 is deposited or grown on the first planarization layer N1. For example, although the first planarization layer N1 may be aluminum nitride (AlN) for high heat dissipation and the second planarization layer N2 may be silicon oxide (SiO2) for easy planarization, and the first planarization layer N1 may be silicon oxide (SiO2) for increased bonding strength and the second planarization layer N2 may be aluminum nitride (AlN) for high heat dissipation, the present invention is not limited thereto and various combinations are possible as needed.

Then, a surface on which the first planarization layer N1 and the second planarization layer N2 are deposited or grown may be planarized through the CMP process, and a degree of planarization may be controlled according to the physical properties of the first planarization layer N1 or the second planarization layer N2. That is, as shown in FIG. 16, when the first planarization layer N1 is aluminum nitride (AlN) and the second planarization layer N2 is silicon oxide (SiO2), it is preferable that the second planarization layer N2 is mostly etched in terms of heat dissipation (case 3 of FIG. 16), and when the first planarization layer N1 is silicon oxide (SiO2) and the second planarization layer N2 is aluminum nitride (AlN), it is preferable that the second planarization layer N2 is hardly etched in terms of heat dissipation (case 1 of FIG. 16).

The eighth operation S408 is an operation of forming a first bonding layer B1 on the group III nitride semiconductor layer C. Here, the first bonding layer B1 may contain a metal such as aluminum (Al), tungsten (W), or molybdenum (Mo) or an alloy thereof, silicon oxide (SiOx), silicon nitride (SiNx), aluminum oxide (Al2O3), aluminum nitride (AlN), aluminum gallium nitride (AlGaN), gallium nitride (GaN), indium gallium nitride (InGaN), indium nitride (InN), amorphous or polycrystalline silicon (Si), zinc oxide (ZnO), C60 (fullerene), or furthermore, may additionally contain a flowable oxide (FOx) such as SOG or hydrogen silsesquioxane (HSQ) to improve surface roughness. In particular, it is preferable to use a CVD process such as an MOCVD or ALD process for aluminum nitride (AlN), aluminum gallium nitride (AlGaN), gallium nitride (GaN), indium gallium nitride (InGaN), and indium nitride (InN) materials.

The ninth operation S409 is an operation of forming the second bonding layer B2 on the support substrate S. Here, like the first bonding layer B1, the second bonding layer B2 may contain a metal such as aluminum (Al), tungsten (W), or molybdenum (Mo) or an alloy thereof, silicon oxide (SiOx), silicon nitride (SiNx), aluminum oxide (Al2O3), aluminum nitride (AlN), aluminum gallium nitride (AlGaN), gallium nitride (GaN), indium gallium nitride (InGaN), indium nitride (InN), amorphous or polycrystalline silicon (Si), zinc oxide (ZnO), C60 (fullerene), or furthermore, may additionally contain a flowable oxide (FOx) such as SOG or hydrogen silsesquioxane (HSQ) to improve surface roughness. In particular, it is preferable to use a CVD process such as an MOCVD or ALD process for aluminum nitride (AlN), aluminum gallium nitride (AlGaN), gallium nitride (GaN), inidium gallium nitride (InGaN), and indium nitride (InN) materials.

Meanwhile, the first bonding layer B1 and the second bonding layer B2 may each include a bonding reinforcement layer R, a surface planarization layer F, and a bonding layer J.

FIG. 9 shows in detail the first bonding layer B1 and the second bonding layer B2 that are manufactured by the method of manufacturing a group III nitride semiconductor template according to the first and second embodiments of the present invention.

As shown in FIG. 9, the bonding reinforcement layer R is formed to reinforce bonding with the group III nitride semiconductor layer C (in the case of the first bonding layer B1) or the support substrate S (in the case of the second bonding layer B2), and the bonding reinforcement layer R may contain, for example, silicon oxide (SiOx), silicon nitride (SiNx), chromium (Cr), titanium (Ti), molybdenum (Mo), or HMDS.

The surface planarization layer F is formed to decrease the surface roughness of the group III nitride semiconductor layer C or the support substrate S, and the surface planarization layer F may contain, for example, silicon oxide (SiOx), silicon nitride (SiNx), aluminum oxide (Al2O3), aluminum nitride (AlN), or amorphous or polycrystalline silicon (Si) to improve surface roughness. Furthermore, the surface planarization layer F may additionally contain a flowable oxide (FOx) such as SOG and HSQ.

The bonding layer J is formed to bond the first bonding layer B1 and the second bonding layer B2, may be made of a permanent bonding material, may contain a metal such as aluminum (Al), tungsten (W), or molybdenum (Mo) or an alloy thereof, silicon oxide (SiOx), silicon nitride (SiNx), aluminum oxide (Al2O3), aluminum nitride (AlN), aluminum gallium nitride (AlGaN), gallium nitride (GaN), indium gallium nitride (InGaN), indium nitride (InN), amorphous or polycrystalline silicon (Si), zinc oxide (ZnO), C60 (fullerene), or furthermore, additionally contain a flowable oxide (FOX) such as SOG or hydrogen silsesquioxane (HSQ) to improve surface roughness. In particular, it is preferable to use a CVD process such as an MOCVD or ALD process for aluminum nitride (AlN), aluminum gallium nitride (AlGaN), gallium nitride (GaN), indium gallium nitride (InGaN), and indium nitride (InN) materials.

Meanwhile, the bonding reinforcement layer R and the surface planarization layer F may be selectively introduced or omitted according to a process, and when the bonding reinforcement layer R and the surface planarization layer F are omitted according to the process, the bonding layer J may be directly deposited on the group III nitride semiconductor layer C (in the case of the first bonding layer B1) or the support substrate S (in the case of the second bonding layer B2).

The tenth operation S410 is an operation of forming the bonding layer B by bonding the first bonding layer B1 and the second bonding layer B2. That is, the tenth operation is an operation of turning over the growth substrate G on which the first bonding layer B1 has been formed (deposited) and the temporary substrate T and pressing and bonding the growth substrate G to the support substrate S on which the second bonding layer B2 has been formed at a temperature of lower than 300° C.

Normally, to minimize wafer bowing after bonding, it is optimal to select the material of the support substrate S so that a difference in CTE with the growth substrate G may be less than 2 ppm, but the polycrystalline aluminum nitride (AlN) ceramic support substrate S having high heat dissipation performance has a difference in CTE of 2 ppm or more from the temporary substrate T, realistically making it difficult to bond the wafer at a high temperature. In this case, it is possible to minimize stress by setting a bonding process temperature to about room temperature and performing the process, thereby preventing wafer bowing.

The eleventh operation S411 is an operation of separating the temporary substrate T from the adhesive layer A using an LLO technique.

The twelfth operation S412 is an operation of separating the adhesive layer A from the nitride semiconductor layer C having the group III metal polarity (M-polarity) surface. Then, the contaminated group III metal (M) polarity surface residue may be removed.

In particular, the twelfth operation S412 is an operation of reinforcing the weak bonding layer B formed between the first bonding layer B1 and the second bonding layer B2 by annealing the group III nitride semiconductor layer C from which the temporary substrate T has been separated at a high temperature of 700° C. or higher before the thirteenth operation S413 of growing the element active layer U structure.

The thirteenth operation S413 is an operation of growing the element active layer U on the nitride semiconductor layer C having the group III metal (M) polarity surface. That is, through the previous operations, a semiconductor element active layer U structure containing a desired compound may be finally grown on the upper surface of the group III nitride semiconductor layer C formed on the high heat dissipation support substrate S. For example, in the case of the GaN material-based power semiconductor structure, the element active layer U may be typically formed by stacking four regions: 1) a GaN buffer layer (horizontal and vertical transistors), 2) a GaN channel layer (horizontal transistor) or a drift layer (vertical transistor), 3) an AlGaN barrier layer (horizontal transistor) or a p-type nitride semiconductor layer (vertical transistor), and 4) a capping passivation layer (horizontal transistor), a p-type nitride semiconductor layer (horizontal transistor), or a capping passivation layer (vertical transistor).

According to the method S400 of manufacturing a group III nitride semiconductor template according to the second embodiment of the present invention, which includes the first operation S401, the second operation S402, the third operation S403, the fourth operation S404, the fifth operation S405, the sixth operation S406, the seventh operation S407, the eighth operation S408, the ninth operation S409, the tenth operation S410, the eleventh operation S411, the twelfth operation S412, and the thirteenth operation S413, and the group III nitride semiconductor template manufactured using the same, the high heat dissipation support substrate S having a CTE that is the same as or similar to that of the group III nitride semiconductor layer C and the group III nitride single crystalline growth layer for the high-quality group III nitride thin film material and the power semiconductor device structure growth using the same may be bonded through a high heat-resistant bonding layer, thereby enabling the formation of a high-quality group III nitride semiconductor layer at a high temperature of 700° C. or higher. That is, since the group III nitride thin film material and the power semiconductor device structure using the same and the support substrate can have the same or similar lattice constant and CTE, it is possible to minimize structural stress and thermo-mechanical induced stress occurring during growth.

In addition, according to the present invention, since the pattern P may be formed to a preset depth by etching the group III nitride semiconductor layer C or the bonding layer B, it is advantageous for the wafer bonding process. That is, in the case of direct wafer bonding, it is quite sensitive to the surface roughness of the surface on which the wafer is bonded and wafer bowing, but according to the patterning of the present invention, there is an advantage in that the strict wafer surface roughness and bowing issue can be considerably alleviated. In addition, according to the patterning of the present invention, since gas generated inside the bonding layer B during the wafer bonding process can be easily discharged, the bonding strength of the bonding layer B can be reinforced in a void-free manner, and structural stress and thermo-mechanical induced stress can also be more effectively buffered.

In addition, according to the present invention, since the high heat dissipation support substrate S is made of a polycrystalline ceramic, there is an advantage in that the high heat dissipation support substrate is better than a single crystalline ceramic in terms of cost competitiveness.

In addition, according to the present invention, the polarity of the surface of the semiconductor layer C initially grown on the growth substrate G and the polarity of the surface of the semiconductor layer C finally formed on the support substrate S may be the same. To successfully execute this, a process for converting the rough surface due to the above-described laser damage region formed during the process and the ID and IDB that are inherently present, etc., into a mirror-like surface should be introduced.

As described above, although all the components constituting embodiments disclosed herein were described as being combined or combined to operate as one, the present invention is not necessarily limited to these embodiments. That is, one or more of all the components may be combined to operate as one without departing from the scope of the purpose of the present invention.

In addition, the terms such as “comprise,” “constitute,” or “have” described above mean that the corresponding component may be inherent unless otherwise stated, and thus should be construed as further including another component rather than excluding another component. All terms including technical or scientific terms have the same meanings as commonly understood by those skilled in the art to which the present invention pertains unless defined otherwise. Commonly used terms, such as terms defined in a dictionary, should be interpreted as being consistent with the contextual meaning of the related art and are not interpreted in an ideal or excessively formal meaning unless explicitly defined herein.

In addition, the above description is merely the exemplary description of the technical spirit of the present invention, and those skilled in the art to which the present invention pertains will be able to variously modify and change the present invention without departing from the essential characteristics of the present invention.

Therefore, the embodiments disclosed in the present invention are not intended to limit the technical spirit of the present invention, but intended to describe the same, and the scope of the technical spirit of the present invention is not limited by these embodiments. The scope of the present invention should be construed by the appended claims, and all technical ideas within the equivalent scope should be construed as being included in the scope of the present invention.

1. A method of manufacturing a group III nitride semiconductor template, comprising:
a first operation of preparing a growth substrate and a support substrate;
a second operation of growing a semiconductor layer on the growth substrate;
a third operation of forming a first bonding layer on the semiconductor layer;
a fourth operation of forming a second bonding layer on the support substrate;
a fifth operation of bonding the first bonding layer and the second bonding layer to form a bonding layer;
a sixth operation of separating the growth substrate from the semiconductor layer; and
a seventh operation of forming a polarity transform layer for transforming a surface polarity of the semiconductor layer into a group III metal polarity on the semiconductor layer.

2. The method of claim 1, wherein the sixth operation includes separating the growth substrate from the semiconductor layer using a laser lift off (LLO) technique.

3. The method of claim 1, further comprising an eighth operation of growing an element active layer on the polarity transform layer.

4. The method of claim 1, wherein the seventh operation includes etching the polarity transform layer to form a plurality of patterns.

5. The method of claim 1, wherein the seventh operation includes etching the semiconductor layer to form a plurality of regular patterns and forming the polarity transform layer along the patterns of the semiconductor layer.

6. The method of claim 1, wherein the seventh operation includes etching the semiconductor layer to form a plurality of irregular patterns, planarizing an end portion of each of the patterns, and then forming the polarity transform layer along the patterns of the semiconductor layer.

7. The method of claim 1, wherein each of the first bonding layer and the second bonding layer includes:
a bonding reinforcement layer configured to reinforce bonding with the support substrate or the semiconductor layer;
a surface planarization layer configured to decrease a surface roughness of the support substrate or the semiconductor layer; and
a bonding layer configured to bond the first bonding layer and the second bonding layer.

8. The method of claim 1, wherein the support substrate is a polycrystalline aluminum nitride (AlN) ceramic substrate.

9. A method of manufacturing a group III nitride semiconductor template, comprising:
a first operation of preparing a growth substrate, a temporary substrate, and a support substrate;
a second operation of growing a semiconductor layer on the growth substrate;
a third operation of forming a first adhesive layer on the semiconductor layer;
a fourth operation of forming a second adhesive layer on the temporary substrate;
a fifth operation of attaching the first adhesive layer to the second adhesive layer to form an adhesive layer;
a sixth operation of separating the growth substrate from the semiconductor layer;
a seventh operation of converting a rough surface of the semiconductor layer, from which the growth substrate has been separated, into a mirror-like surface;
an eighth operation of forming a first bonding layer on the semiconductor layer;
a ninth operation of forming a second bonding layer on the support substrate;
a tenth operation of bonding the first bonding layer and the second bonding layer to form a bonding layer;
an eleventh operation of separating the temporary substrate from the adhesive layer; and
a twelfth operation of separating the adhesive layer from the semiconductor layer.

10. The method of claim 9, wherein the sixth operation includes separating the growth substrate from the semiconductor layer using a laser lift off (LLO) technique, and
the eleventh operation includes separating the temporary substrate from the adhesive layer using an LLO technique.

11. The method of claim 9, further comprising a thirteenth operation of growing an element active layer on the semiconductor layer.

12. The method of claim 9, wherein the seventh operation includes making the semiconductor layer have a mirror-like surface by forming a planarization layer on the semiconductor layer and then planarizing the planarization layer.

13. The method of claim 9, wherein the seventh operation includes making the semiconductor layer have a mirror-like surface by directly planarizing an upper surface of the semiconductor layer.

14. The method of claim 9, wherein the seventh operation includes making the semiconductor layer have a mirror-like surface by etching an upper surface of the semiconductor layer to form a plurality of patterns, forming a first planarization layer along the patterns of the semiconductor layer, forming a second planarization layer on the first planarization layer, and planarizing the first planarization layer or the second planarization layer.

15. The method of claim 9, wherein each of the first bonding layer and the second bonding layer includes:
a bonding reinforcement layer configured to reinforce bonding with the support substrate or the semiconductor layer;
a surface planarization layer configured to decrease a surface roughness of the support substrate or the semiconductor layer; and
a bonding layer configured to bond the first bonding layer and the second bonding layer.

16. The method of claim 9, wherein the support substrate is a polycrystalline aluminum nitride (AlN) ceramic substrate.

17. A group III nitride semiconductor template manufactured by the method of manufacturing a group III nitride semiconductor template of claim 1.
